(19) United States
(12) Patent Application Publication
(10) Pub. No.: US 2025/0015152 A1
(43) Pub. Date: Jan. 9, 2025

(54) NITRIDE SEMICONDUCTOR DEVICE

(71) Applicant: ROHM CO., LTD., Kyoto-shi (JP)

(72) Inventors: Manabu YANAGIHARA, Kyoto-shi (JP); Kazuya NAGASE, Kyoto-shi (JP); Shinya TAKADO, Kyoto-shi (JP); Hirotaka OTAKE, Kyoto-shi (JP)

(73) Assignee: ROHM CO., LTD., Kyoto-shi (JP)

(21) Appl. No.: 18/890,816

(22) Filed: Sep. 20, 2024

Related U.S. Application Data
(63) Continuation of application No. PCT/JP2023/006618, filed on Feb. 24, 2023.

(30) Foreign Application Priority Data
Mar. 29, 2022 (JP) 2022-053891

(51) Int. Cl. H01L 29/417; H01L 21/285; H01L 29/20; H01L 29/40; H01L 29/45; H01L 29/66; H01L 29/778

(52) U.S. Cl. CPC H01L 29/41766; H01L 21/28587; H01L 29/2003; H01L 29/402; H01L 29/452; H01L 29/66462; H01L 29/7786

(57) ABSTRACT

A nitride semiconductor device includes: an electron transit layer; an electron supply layer that is formed on the electron transit layer and that has a band gap which is larger than that of the electron transit layer; a dielectric layer that is formed on the electron supply layer; and an electrode that has a contact part which is in electrical contact with the electron supply layer via at least an opening passing through the dielectric layer. The contact part has: an inclined surface that is inclined so as to decrease in width toward the electron transit layer; a tip surface that is in contact with the bottom face of the opening; and a curved surface that is provided between the tip surface and the inclined surface and that is curved so as to protrude toward the electron transit layer.

### CROSS-REFERENCE TO RELATED APPLICATIONS

This application is a continuation of, and claims the benefit of priority from International Application No. PCT/JP2023/006618, filed on Feb. 24, 2023, which claims the benefit of priority from Japanese Patent Application No. 2022-053891, filed on Mar. 29, 2022, the entire contents of each of which are incorporated herein by reference.

### BACKGROUND

### 1. Field

The present disclosure relates to a nitride semiconductor device.

### 2. Description of Related Art

High-electron-mobility transistors (HEMT) that use nitride semiconductors are now being commercialized (refer to, for example, Japanese Laid-Open Patent Publication No. 2017-73506). The HEMT includes, for example, an electron transit layer formed of a GaN layer, an electron supply layer formed on the electron transit layer and formed of an AlGaN layer, a gate layer formed on the electron supply layer and formed of a p-type GaN layer, a gate electrode formed on the gate layer, and a passivation layer covering the electron supply layer, the gate layer, and the gate electrode. High density of two-dimensional electron gas (2DEG) is generated in the interface between the electron transit layer and the electron supply layer at a location near the electron transit layer. The passivation layer includes a source opening and a drain opening that expose the electron supply layer. The HEMT further includes a source electrode and a drain electrode. The source electrode is in ohmic contact with the 2DEG via the electron supply layer exposed by the source opening. The drain electrode is in ohmic contact with the 2DEG via the electron supply layer exposed by the drain opening.

### BRIEF DESCRIPTION OF THE DRAWINGS

FIG. 1 is a schematic cross-sectional view of an exemplary nitride semiconductor device according to a first embodiment.

FIG. 2 is an enlarged cross-sectional view showing a portion of the nitride semiconductor device shown in FIG. 1.

FIG. 3 is a schematic cross-sectional view showing an exemplary manufacturing step of the nitride semiconductor device shown in FIG. 1.

FIG. 4 is a schematic cross-sectional view showing a manufacturing step subsequent to FIG. 3.

FIG. 5 is a schematic cross-sectional view showing a manufacturing step subsequent to FIG. 4.

FIG. 6 is a schematic cross-sectional view showing a manufacturing step subsequent to FIG. 5.

FIG. 7 is a schematic cross-sectional view illustrating a manufacturing step following the step of FIG. 6.

FIG. 8 is a schematic cross-sectional view showing a manufacturing step subsequent to FIG. 7.

FIG. 9 is a schematic cross-sectional view of an exemplary nitride semiconductor device according to a comparative example.

FIG. 10 is a graph showing the relationship between contact resistance and a position of a distal surface of a contact of an electrode.

FIG. 11 is a schematic cross-sectional view of an exemplary nitride semiconductor device according to a second embodiment.

FIG. 12 is a schematic cross-sectional view of an exemplary nitride semiconductor device according to a third embodiment.

FIG. 13 is a schematic cross-sectional view of an exemplary nitride semiconductor device according to a fourth embodiment.

FIG. 14 is a schematic cross-sectional view of an exemplary nitride semiconductor device according to a fifth embodiment.

FIG. 15 is a schematic plan view showing an exemplary formation pattern in the nitride semiconductor device shown in FIG. 14.

FIG. 16 is a schematic cross-sectional view showing a modified example of a nitride semiconductor device.

FIG. 17 is a schematic cross-sectional view showing a modified example of a nitride semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

### Structure of Nitride Semiconductor Device

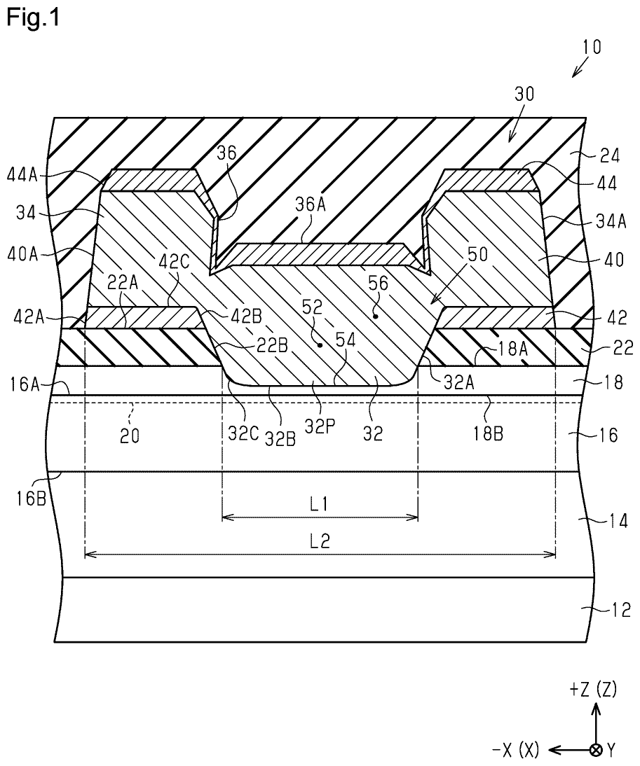

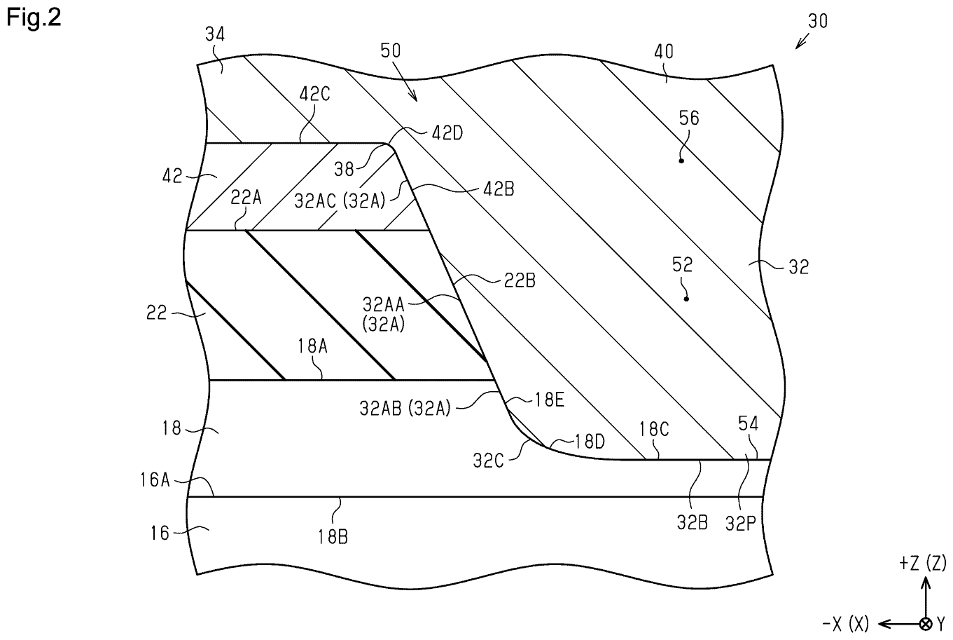

The structure of a first embodiment of a nitride semiconductor device 10 will now be described with reference to FIGS. 1 and 2.

FIG. 1 shows a schematic cross-sectional structure of an exemplary nitride semiconductor device 10 in the first embodiment. As shown in FIG. 1, the X-axis, the Y-axis, and the Z-axis are orthogonal to one another. The term “plan view” as used in the present disclosure is a view of the nitride semiconductor device 10 taken in the Z-axis direction. Further, in FIG. 1, which shows the nitride semiconductor device 10, the +Z direction corresponds to the upward direction, the −Z direction corresponds to the downward direction, the +X direction corresponds to the rightward direction, and the −X direction corresponds to the leftward direction. Unless otherwise indicated, the term “plan view” will refer to a view of the nitride semiconductor device 10 taken from above along the Z-axis.

A III-V semiconductor is used in the nitride semiconductor device 10. In the first embodiment, a group-III nitride semiconductor is used as the III-V semiconductor. The group-III nitride semiconductor refers to a III-V semiconductor in which nitrogen is used as a group-V element. Representative examples include gallium nitride (GaN), aluminum nitride (AlN), and indium nitride (InN). A typical group-III nitride semiconductor may be expressed as AlₓIn_{y}Ga_{1-x-y}N, where 0≤x≤1, 0≤y≤1, 0≤x+y≤1.

The nitride semiconductor device 10 includes a substrate 12, a buffer layer 14 formed on the substrate 12, an electron transit layer 16 formed on the buffer layer 14, and an electron supply layer 18 formed on the electron transit layer 16.

In an example, a silicon (Si) substrate may be used as the substrate 12. Alternatively, a silicon carbide (SiC) substrate, a gallium nitride (GaN) substrate, or a sapphire substrate may be used instead of the Si substrate. The substrate 12 may have a thickness of, for example, 200 μm or greater and 1500 μm or less. The term “thickness” in the following description refers to a dimension extending in the Z-axis direction shown in FIG. 1 unless otherwise indicated.

The buffer layer 14 may be disposed between the substrate 12 and the electron transit layer 16 and may be formed of any material that reduces the lattice mismatching between the substrate 12 and the electron transit layer 16. The buffer layer 14 may include one or more nitride semiconductor layers. The buffer layer 14 may include, for example, at least one of an AlN layer, an aluminum gallium nitride (AlGaN) layer, and a graded AlGaN layer of different aluminum (Al) compositions. In an example, the buffer layer 14 may be composed of a single film of AlN, a single film of AlGaN, a film having a superlattice structure of AlGaN/GaN, a film having a superlattice structure of AlN/AlGaN, or a film having a superlattice structure of AlN/GaN.

In an example, the buffer layer 14 includes a first buffer layer, which is an AlN layer formed on the substrate 12, and a second buffer layer, which is an AlGaN layer formed on the AlN layer (first buffer layer). The first buffer layer may be an AlN layer having a thickness of 200 nm, and the second buffer layer may be a graded AlGaN layer having a thickness of 300 nm. To reduce leakage current in the buffer layer 14, part of the buffer layer 14 may include an impurity so that regions other than an outer layer region of the buffer layer 14 are semi-insulating. In this case, the impurity may be, for example, carbon (C) or iron (Fe). The concentration of the impurity may be, for example, 4×10¹⁶ cm⁻³ or greater. The thickness of the buffer layer 14 may be greater than 500 nm. In an example, the thickness of the buffer layer 14 is 1500 nm.

The electron transit layer 16 is composed of a nitride semiconductor. The electron transit layer 16 may be, for example, a GaN layer. The electron transit layer 16 may have a thickness of, for example, 0.5 μm or greater and 2 μm or less. In an example, the thickness of the electron transit layer 16 is 1 μm. The electron transit layer 16 includes a head surface 16A and a back surface 16B opposite to the head surface 16A. The back surface 16B is in contact with the buffer layer 14. The head surface 16A is in contact with the electron supply layer 18.

To inhibit current leakage in the electron transit layer 16, a portion of the electron transit layer 16 may be doped with an impurity so that the electron transit layer 16 excluding the outer layer region becomes semi-insulating. In this case, the impurity may be, for example, carbon (C). The concentration of the impurity may be, for example, 4×10¹⁶ cm⁻³ or greater. The electron transit layer 16 may include GaN layers of different impurity concentrations, for example, a carbon-doped GaN layer and a non-doped GaN layer. In this case, the carbon-doped GaN layer is formed on the buffer layer 14. The carbon-doped GaN layer may have a thickness of 0.5 μm or greater and 2 μm or less. The carbon-doped GaN layer may have a carbon concentration of 5×10¹⁷ cm⁻³ or greater and 9×10¹⁹ cm⁻³ or less. The non-doped GaN layer is formed on the carbon-doped GaN layer. The non-doped GaN layer may have a thickness of 0.05 μm or greater and 0.4 μm or less. The non-doped GaN layer is in contact with the electron supply layer 18. In an example, the electron transit layer 16 includes a carbon-doped GaN layer having a thickness of 0.9 μm and a non-doped GaN layer having a thickness of 0.1 μm. The carbon-doped GaN layer has a carbon concentration of approximately 1×10¹⁸ cm⁻³.

The electron supply layer 18 is composed of a nitride semiconductor having a bandgap that is larger than that of the electron transit layer 16. The electron supply layer 18 may be, for example, an AlGaN layer. A nitride semiconductor will have a larger bandgap as the Al composition increases. Thus, the electron supply layer 18, which is an AlGaN layer, has a larger bandgap than the electron transit layer 16, which is a GaN layer. In an example, the electron supply layer 18 is composed of AlₓGa₁₋ₓN. That is, the electron supply layer 18 is an AlₓGa₁₋ₓN layer, where 0<x<0.4, preferably, 0.1≤x≤0.3, and more preferably, 0.2≤x≤0.3. When the electron supply layer 18 is the AlₓGa₁₋ₓN layer, the range of x may be changed in any manner.

The electron supply layer 18 includes a head surface 18A and a back surface 18B opposite to the head surface 18A. The back surface 18B is in contact with the electron transit layer 16. The head surface 18A is in contact with a dielectric layer 22. The electron supply layer 18 may have a thickness of, for example, 5 nm or greater and 20 nm or less. In an example, the thickness of the electron supply layer 18 is approximately 10 nm.

The electron transit layer 16 and the electron supply layer 18 have different lattice constants in a bulk region. Thus, the electron transit layer 16 and the electron supply layer 18 are lattice-mismatched junctions. In the vicinity of the heterojunction interface between the electron transit layer 16 and the electron supply layer 18, the energy level in the conductive band of the electron transit layer 16 is lower than the Fermi level due to spontaneous polarization of the electron transit layer 16 and the electron supply layer 18 and piezoelectric polarization caused by compressive stress received by the heterojunction of the electron transit layer 16. Thus, two-dimensional electron gas (2DEG) 20 spreads in the electron transit layer 16 at a location proximate to (e.g., distanced by approximately a few nanometers from interface) the heterojunction interface of the electron transit layer 16 and the electron supply layer 18. The density of the 2DEG 20 is, for example, approximately 1×10¹³ cm⁻² but is not particularly limited.

The nitride semiconductor device 10 further includes the dielectric layer 22, an insulation layer 24, and an electrode 30.

The dielectric layer 22 is formed on the electron supply layer 18. In other words, the dielectric layer 22 covers the electron supply layer 18. The dielectric layer 22 may be composed of a material containing one of, for example, silicon nitride (SiN), silicon dioxide (SiO₂), silicon oxynitride (SiON), alumina (Al₂O₃), aluminum nitride (AlN), and aluminum oxynitride (AlON). In an example, the dielectric layer 22 is formed from a material including SiN. The dielectric layer 22 may be referred to as a passivation layer. The dielectric layer 22 is greater in thickness than the electron supply layer 18. In an example, the thickness of the dielectric layer 22 is approximately 100 nm. The thickness of the dielectric layer 22 may be changed in any manner.

The electrode 30 includes a contact 32 in electrical contact with the electron supply layer 18 through an opening 50, which extends through at least the dielectric layer 22. The electrode 30 includes an interconnect 34 formed on the dielectric layer 22.

The contact 32 is in ohmic contact with the 2DEG 20 via the opening 50. Hence, the electrode 30 may be referred to as an ohmic electrode. The interconnect 34 extends out of the opening 50 in a width-wise direction (in FIG. 1, X-axis direction) of the electrode 30. In plan view, the interconnect 34 is located inward from the peripheral edges (not shown) of the dielectric layer 22, the electron supply layer 18, and the like.

The interconnect 34 includes a portion that corresponds to the contact 32 and is recessed toward the electron supply layer 18, defining a valley 36. The valley 36 includes a bottom surface 36A. The bottom surface 36A and the electron supply layer 18 are located at opposite sides of the dielectric layer 22. In plan view, the valley 36 overlaps the opening 50.

The electrode 30 includes an electrode layer 40, a first barrier layer 42, and a second barrier layer 44. The electrode 30 has a stacked structure of the electrode layer 40, the first barrier layer 42, and the second barrier layer 44. The contact 32 is composed of only the electrode layer 40. The interconnect 34 is composed of the stacked structure of the electrode layer 40, the first barrier layer 42, and the second barrier layer 44.

The first barrier layer 42 is formed on the dielectric layer 22. The first barrier layer 42 may be composed of a material including any of titanium nitride (TiN), tungsten silicon nitride (WSiN), and tungsten nitride (WN). In an example, the first barrier layer 42 is formed from a material including TiN. The first barrier layer 42 is smaller in thickness than the dielectric layer 22. In an example, the thickness of the first barrier layer 42 is approximately 50 nm.

The electrode layer 40 includes a portion formed on the first barrier layer 42. The electrode layer 40 includes a portion disposed between the first barrier layer 42 and the second barrier layer 44. Thus, the first barrier layer 42 is sandwiched between the dielectric layer 22 and the electrode layer 40. The electrode layer 40 includes at least Ti and Al. The electrode layer 40 may include, for example, AlCu and Ti. The electrode layer 40 is composed of one or more metal layers. In an example, the electrode layer 40 has a stacked structure of a first metal layer, a second metal layer, and a third metal layer. The first metal layer is formed from a material including, for example, Ti. The first metal layer has a thickness of approximately 20 nm. The second metal layer is formed on the first metal layer. The second metal layer is formed from a material including AlCu. The second metal layer is, for example, an alloy of Al to which approximately 1% or less of Cu is added. The second metal layer has a thickness that is approximately 200 nm. The third metal layer is formed on the second metal layer. The third metal layer is formed from a material including Ti. Thus, the electrode layer 40 includes at least Ti, Al, and Cu. In other words, the electrode 30 includes at least Ti, Al, and Cu. The third metal layer has a thickness of approximately 20 nm. Thus, the electrode layer 40 is greater in thickness than each of the first barrier layer 42 and the dielectric layer 22.

The second barrier layer 44 and the first barrier layer 42 are disposed at opposite sides of the interconnect 34. The second barrier layer 44 is formed along the valley 36 of the interconnect 34. The second barrier layer 44 may be composed of a material including any of TIN, WSiN, and WN. In an example, the second barrier layer 44 is formed from a material including TiN. That is, the second barrier layer 44 and the first barrier layer 42 are formed from the same material. The second barrier layer 44 and the first barrier layer 42 have, for example, the same thickness. In an example, the thickness of the second barrier layer 44 is approximately 50 nm. As shown in FIG. 1, the thickness of the second barrier layer 44 varies. The thickness of a portion of the second barrier layer 44 overlapping the first barrier layer 42 in plan view is approximately 50 nm.

As shown in FIG. 1, the interconnect 34 includes an outer surface 34A that is inclined so that the interconnect 34 has a width that decreases as the dielectric layer 22 becomes farther away in the Z-axis direction. More specifically, in the interconnect 34, an outer surface 42A of the first barrier layer 42, an outer surface 40A of the electrode layer 40, and an outer surface 44A of the second barrier layer 44 are each inclined so that the width decreases as the dielectric layer 22 becomes farther away in the Z-axis direction. The inclination angle of the outer surface 42A of the first barrier layer 42 with respect to the Z-axis direction is equal to the inclination angle of the outer surface 40A of the electrode layer 40 with respect to the Z-axis direction. The outer surface 42A is continuous and flush with the outer surface 40A. The inclination angle of the second barrier layer 44 with respect to the Z-axis direction is greater than the inclination angle of the outer surface 40A of the electrode layer 40 with respect to the Z-axis direction.

The insulation layer 24 is formed to cover the interconnect 34 of the electrode 30 and a portion of the dielectric layer 22 exposed from the electrode 30. Thus, the insulation layer 24 is formed on the second barrier layer 44. Further, the insulation layer 24 is in contact with the outer surface 40A of the electrode layer 40, the outer surface 42A of the first barrier layer 42, and the outer surface 44A of the second barrier layer 44 in the interconnect 34, and a surface 22A of the dielectric layer 22. The insulation layer 24 is formed from a material including, for example, SiO₂. The material forming the insulation layer 24 may be changed in any manner and may be, for example, SiON or SiN.

In the first embodiment, a length L2 of the interconnect 34 in the X-axis direction is at least twice a length L1 of a distal portion 32P of the contact 32 in the X-axis direction. The length L2 of the interconnect 34 in the X-axis direction indicates the maximum length of the interconnect 34 in the X-axis direction. That is, the length L2 is defined by the length, in the X-axis direction, of the portion of the outer surface 42A of the first barrier layer 42 that is in contact with the dielectric layer 22. The length L1 of the distal portion 32P of the contact 32 in the X-axis direction is defined by the width of a portion of the contact 32 located in the interface between the dielectric layer 22 and the electron supply layer 18 in the Z-axis direction.

The structures of the opening 50 and the contact 32 of the electrode 30 in the opening 50 will now be described in detail with reference to FIGS. 1 and 2. FIG. 2 is an enlarged partial view of the opening 50 and the contact 32 shown in FIG. 1.

As shown in FIG. 1, in the first embodiment, the opening 50 extends through the dielectric layer 22 and is formed in at least a portion of the electron supply layer 18. More specifically, the opening 50 includes a through portion 52 extending through the dielectric layer 22 and a recess 54 disposed in the electron supply layer 18 and continuous with the through portion 52.

The contact 32 is formed of the electrode layer 40. The contact 32 extends through the first barrier layer 42. Thus, the opening 50 includes a barrier through portion 56, which extends through the first barrier layer 42. In the first embodiment, the contact 32 extends through the first barrier layer 42 and the dielectric layer 22. The contact 32 does not extend through the electron supply layer 18.

As shown in FIG. 2, the barrier through portion 56 is defined by an inner surface 42B that defines the opening in the first barrier layer 42. The inner surface 42B is inclined so that the opening width of the barrier through portion 56 decreases toward the electron transit layer 16. The opening width of the barrier through portion 56 is defined by the dimension of the barrier through portion 56 in the X-axis direction.

The through portion 52 is defined by an inner surface 22B that defines the opening in the dielectric layer 22. The inner surface 22B is inclined so that the opening width of the through portion 52 decreases toward the electron transit layer 16. The opening width of the through portion 52 is defined by the dimension of the through portion 52 in the X-axis direction. In the first embodiment, the inclination angle of the inner surface 22B with respect to the Z-axis direction is equal to the inclination angle of the inner surface 42B of the first barrier layer 42 with respect to the Z-axis direction. The inner surface 22B is continuous and flush with the inner surface 42B.

The recess 54 includes a recess bottom surface 18C formed in the electron supply layer 18 and recess curved surfaces 18D formed on two ends of the recess bottom surface 18C in the X-axis direction. The recess 54 further includes a recess inclined surface 18E continuous with the recess curved surfaces 18D at a side opposite to the recess bottom surface 18C.

The recess bottom surface 18C is disposed closer to the back surface 18B than to the head surface 18A of the electron supply layer 18. In the first embodiment, the recess bottom surface 18C is disposed closer to the back surface 18B than the center of the electron supply layer 18 in the thickness-wise direction (Z-axis direction) is. The recess bottom surface 18C extends in the X-axis direction. The recess bottom surface 18C defines the bottom of the opening 50.

The recess curved surface 18D is curved and recessed toward the electron transit layer 16. Thus, the recess curved surface 18D has a center of curvature located toward the dielectric layer 22 with respect to the recess bottom surface 18C.

The recess inclined surface 18E is inclined so that the width of the opening 50 decreases toward the recess curved surfaces 18D. The width of the opening 50 may be defined by the dimension of the opening 50 in the X-axis direction. In the first embodiment, the inclination angle of the recess inclined surface 18E with respect to the Z-axis direction is equal to the inclination angle of the inner surface 22B of the dielectric layer 22 with respect to the Z-axis direction. The recess inclined surface 18E is continuous and flush with the inner surface 22B. In an example, the inclination angle of the recess inclined surface 18E with respect to the Z-axis direction and the inclination angle of the inner surface 22B of the dielectric layer 22 with respect to the Z-axis direction are each 10° or greater and 20° or less. In the first embodiment, the inclination angle of the recess inclined surface 18E with respect to the Z-axis direction and the inclination angle of the inner surface 22B of the dielectric layer 22 with respect to the Z-axis direction are each 15°.

The contact 32 of the electrode 30 is embedded in the opening 50. The contact 32 is a portion of the electrode 30 located closer to the electron transit layer 16 than a surface 42C of the first barrier layer 42 is. The contact 32 includes an inclined surface 32A, which is inclined so that the width of the contact 32 decreases toward the electron transit layer 16, a distal surface 32B in contact with the recess bottom surface 18C, corresponding to the surface defining the bottom of the opening 50, and a curved surface 32C disposed between the distal surface 32B and the inclined surface 32A.

The inclined surface 32A includes a first part 32AA in contact with the dielectric layer 22 and a second part 32AB in contact with the electron supply layer 18. The inclined surface 32A further includes a third part 32AC in contact with the first barrier layer 42.

The first part 32AA is in contact with the inner surface 22B, which defines the through portion 52 of the dielectric layer 22. In the first embodiment, the first part 32AA is in contact with the entirety of the inner surface 22B. Thus, the inclination angle of the first part 32AA with respect to the Z-axis direction is equal to the inclination angle of the inner surface 22B with respect to the Z-axis direction.

The second part 32AB is in contact with the recess inclined surface 18E, which defines the recess 54 of the electron supply layer 18. In the first embodiment, the second part 32AB is in contact with the entirety of the recess inclined surface 18E. Thus, the inclination angle of the second part 32AB with respect to the Z-axis direction is equal to the inclination angle of the recess inclined surface 18E with respect to the Z-axis direction. The inclination angle of the first part 32AA with respect to the Z-axis direction is equal to the inclination angle of the second part 32AB with respect to the Z-axis direction. In an example, the inclination angle of the first part 32AA with respect to the Z-axis direction and the inclination angle of the second part 32AB with respect to the Z-axis direction are each 10° or greater and 20° or less. In the first embodiment, the inclination angle of the first part 32AA with respect to the Z-axis direction and the inclination angle of the second part 32AB with respect to the Z-axis direction are each 15°. In the first embodiment, the first part 32AA is continuous and flush with the second part 32AB. Thus, a boundary portion of the first part 32AA with the second part 32AB is aligned with a boundary portion of the second part 32AB with the first part 32AA in the X-axis direction. In other words, no step is formed between the first part 32AA and the second part 32AB.

The third part 32AC is in contact with the inner surface 42B, which defines the barrier through portion 56 of the first barrier layer 42. In the first embodiment, the third part 32AC is in contact with the entirety of the inner surface 42B. Thus, the inclination angle of the third part 32AC with respect to the Z-axis direction is equal to the inclination angle of the inner surface 42B with respect to the Z-axis direction. The inclination angle of the first part 32AA with respect to the Z-axis direction is equal to the inclination angle of the third part 32AC with respect to the Z-axis direction. In the first embodiment, the first part 32AA is continuous and flush with the third part 32AC. Thus, a boundary portion of the first part 32AA with the third part 32AC is aligned with a boundary portion of the third part 32AC with the first part 32AA in the X-axis direction. In other words, no step is formed between the first part 32AA and the third part 32AC.

The distal surface 32B of the contact 32 extends in the X-axis direction. In the first embodiment, the distal surface 32B is in contact with the electron supply layer 18. More specifically, the distal surface 32B is in contact with the recess bottom surface 18C of the electron supply layer 18 (surface defining the bottom of the opening 50). The recess bottom surface 18C is located closer to the back surface 18B than the center of the electron supply layer 18 in the thickness-wise direction is. Thus, the distal surface 32B is located closer to the electron transit layer 16 than the center of the electron supply layer 18 in the thickness-wise direction of the electron supply layer 18 is.

The curved surface 32C of the contact 32 is convex toward the electron transit layer 16. Thus, the curved surface 32C has a center of curvature located toward the dielectric layer 22 with respect to the distal surface 32B. In the first embodiment, the curved surface 32C is disposed between the head surface 18A and the back surface 18B of the electron supply layer 18 in the Z-axis direction. The curved surface 32C is in contact with the electron supply layer 18. More specifically, the curved surface 32C is in contact with the recess curved surfaces 18D of the electron supply layer 18. The curvature of the curved surface 32C is equal to the curvature of the recess curved surfaces 18D.

The electrode layer 40 includes a connection part 38 between the contact 32 and the interconnect 34. The arc length of the curved surface 32C is greater than the arc length of the connection part 38. More specifically, the connection part 38 has the form of a concave that is recessed toward the valley 36 (refer to FIG. 1) of the interconnect 34. In other words, the first barrier layer 42 includes a barrier curved surface 42D formed between the inner surface 42B, which defines the barrier through portion 56 of the first barrier layer 42, and a surface 42C of the first barrier layer 42. The barrier curved surface 42D is unintentionally formed in a process of forming the barrier through portion 56 in the first barrier layer 42b, for example, during dry etching performed to form the barrier through portion 56. The barrier curved surface 42D is in contact with the connection part 38. Thus, the arc length of the connection part 38 is equal to the arc length of the barrier curved surface 42D. Thus, the arc length of the curved surface 32C is greater than the arc length of the barrier curved surface 42D, which is formed unintentionally.

### Semiconductor Device Manufacturing Method

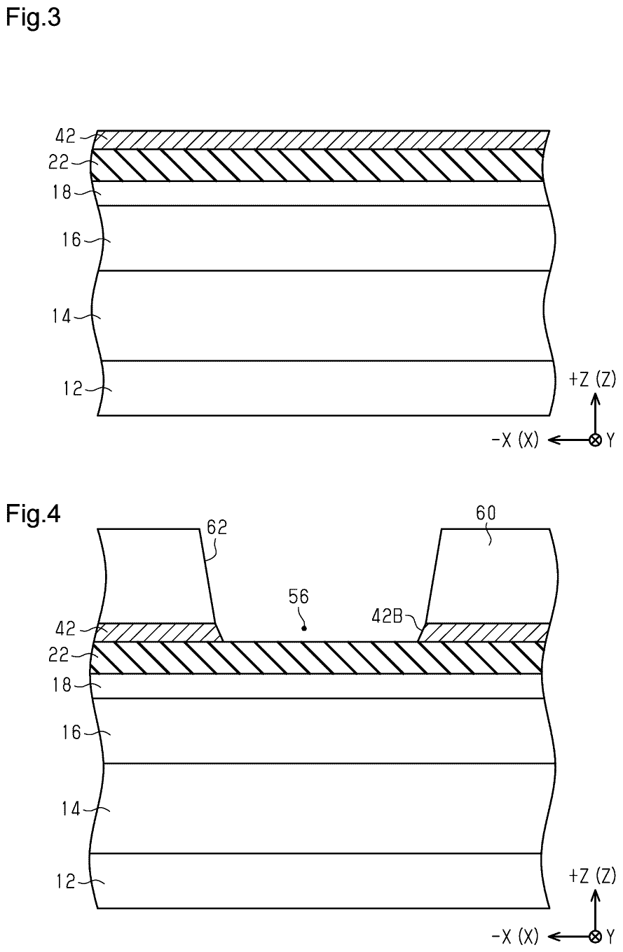

A method for manufacturing the nitride semiconductor device 10 of the first embodiment will now be described with reference to FIGS. 3 to 8. FIGS. 3 to 8 are schematic cross-sectional views showing exemplary manufacturing steps of the nitride semiconductor device 10. To facilitate understanding, members becoming the final elements of the nitride semiconductor device 10 are indicated by the same reference characters as shown in FIG. 1.

As shown in FIG. 3, the method for manufacturing the nitride semiconductor device 10 includes forming the buffer layer 14, the electron transit layer 16, and the electron supply layer 18 on the substrate 12, which is, for example, a Si substrate having <111> plane orientation.

The buffer layer 14, the electron transit layer 16, and the electron supply layer 18 may be epitaxially grown using a metal organic chemical vapor deposition (MOCVD) process.

Although not shown in detail, the buffer layer 14 is, for example, multilayered. An AlN layer (first buffer layer) is formed on the substrate 12, and then a graded AlGaN layer (second buffer layer) is formed on the AlN layer. In an example, the graded AlGaN layer may be formed by stacking three AlGaN layers having Al compositions of 75%, 50%, and 25%, respectively, from the side close to the AlN layer.

Then, a GaN layer is formed as the electron transit layer 16 on the buffer layer 14. An AlGaN layer is formed as the electron supply layer 18 on the electron transit layer 16. Thus, the electron supply layer 18 has a larger bandgap than the electron transit layer 16. The buffer layer 14 has a thickness of, for example, 1.5 μm. The electron transit layer 16 has a thickness of, for example, 1 μm. The electron supply layer 18 has a thickness of, for example, 10 nm.

The method for manufacturing the nitride semiconductor device 10 includes forming the dielectric layer 22 on the electron supply layer 18. In an example, the dielectric layer 22 is a SiN layer formed through plasma-enhanced chemical vapor deposition (PECVD). Alternatively, the dielectric layer 22 may be formed through low-pressure chemical vapor deposition (LPCVD). The dielectric layer 22 has a thickness of, for example, 100 nm.

The method for manufacturing the method for manufacturing the nitride semiconductor device 10 includes forming the first barrier layer 42 on the dielectric layer 22. The first barrier layer 42 is a TiN layer formed through a sputtering process. The first barrier layer 42 has a thickness of 50 nm. Alternatively, the first barrier layer 42 may be a WSiN layer or a WN layer.

As shown in FIG. 4, the method for manufacturing the nitride semiconductor device 10 includes forming the barrier through portion 56 in the first barrier layer 42.

More specifically, a mask 60 including an opening 62 is formed. More specifically, a photoresist is formed on the first barrier layer 42. The photoresist is patterned so that a portion of the first barrier layer 42 is exposed from the photoresist. This forms the mask 60 including the opening 62. The opening 62 is tapered so that the width of the opening 62 decreases toward the first barrier layer 42.

The first barrier layer 42 is removed from a position corresponding to the opening 62 by etching (e.g., dry etching) that uses the mask 60. As a result of the etching, the barrier through portion 56 is formed at the position corresponding to the opening 62. Since the opening 62 is tapered, the inner surface 42B of the first barrier layer 42 defining the barrier through portion 56 also includes an inclined surface so that the opening width of the barrier through portion 56 decreases toward the dielectric layer 22. Formation of the barrier through portion 56 exposes the dielectric layer 22.

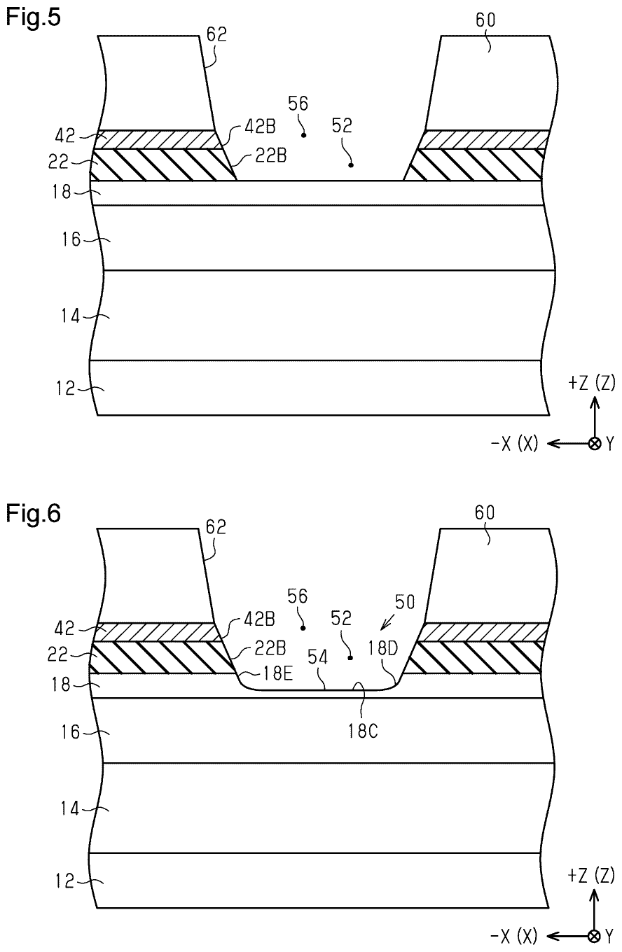

As shown in FIG. 5, the method for manufacturing the nitride semiconductor device 10 includes forming the through portion 52 in the dielectric layer 22.

More specifically, the dielectric layer 22 is removed from a position corresponding to the opening 62 by etching (e.g., dry etching) that uses the mask 60. The etching condition is set so that the electron supply layer 18 will not be damaged by the etching. In an example, bias power applied when forming the through portion 52 in the dielectric layer 22 is less than bias power applied when forming the barrier through portion 56 in the first barrier layer 42. Since the opening 62 is tapered, the inner surface 22B of the dielectric layer 22 defining the through portion 52 also includes an inclined surface so that the opening width of the through portion 52 decreases toward the electron supply layer 18. Further, because of the use of the same mask 60, the inclination angle of the inner surface 42B of the first barrier layer 42 with respect to the Z-axis direction is equal to the inclination angle of the inner surface 22B of the dielectric layer 22 with respect to the Z-axis direction. The inner surface 42B is continuous and flush with the inner surface 22B. Formation of the through portion 52 exposes the electron supply layer 18.

As shown in FIG. 6, the method for manufacturing the nitride semiconductor device 10 includes forming the recess 54 in the electron supply layer 18.

More specifically, the electron supply layer 18 is partially removed from a position corresponding to the opening 62 by etching (e.g., dry etching) that uses the mask 60. The etching condition is set so that the recess 54, that is, the recess bottom surface 18C, the recess curved surfaces 18D, and the recess inclined surface 18E, is formed. Since the opening 62 is tapered, the recess inclined surface 18E includes as an inclined surface so that the width of the recess 54 decreases toward the electron transit layer 16. Because of the use of the same mask 60, the inclination angle of the recess inclined surface 18E with respect to the Z-axis direction is equal to the inclination angle of the inner surface 22B of the dielectric layer 22 with respect to the Z-axis direction. The recess inclined surface 18E is continuous and flush with the inner surface 22B. The inclination angles of the recess inclined surface 18E and the inner surfaces 22B and 42B with respect to the Z-axis direction are each 10° or greater and 20° or less and, in the first embodiment, 15°. The steps described above form the opening 50. After the opening 50 is formed, the mask 60 is removed.

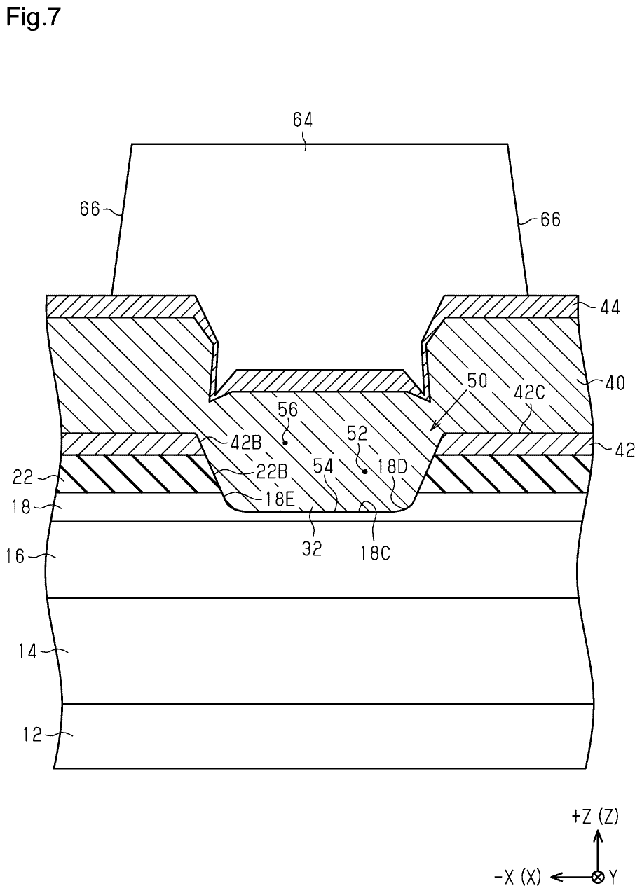

As shown in FIG. 7, the method for manufacturing the nitride semiconductor device 10 includes forming the electrode layer 40 and the second barrier layer 44. The electrode layer 40 and the second barrier layer 44 are formed through a sputtering process.

More specifically, as shown in FIG. 7, a first metal layer is formed to contact the surface 42C and the inner surface 42B of the first barrier layer 42, the inner surface 22B of the dielectric layer 22, and the recess inclined surface 18E, the recess curved surfaces 18D, and the recess bottom surface 18C of the electron supply layer 18. The first metal layer is formed from a material including, for example, Ti. The first metal layer has a thickness of 20 nm. Then, a second metal layer is formed on the first metal layer. The second metal layer is formed from a material including AlCu. The second metal layer is, for example, an alloy of Al to which approximately 1% or less of Cu is added. The second metal layer has a thickness of 200 nm. Then, a third metal layer is formed on the second metal layer. The third metal layer is formed from a material including Ti. The third metal layer has a thickness of approximately 20 nm.

The second barrier layer 44 is formed on the third metal layer. The second barrier layer 44 is a TiN layer formed through a sputtering process. The second barrier layer 44 has a thickness of 50 nm. The steps described above form the contact 32 of the electrode 30. The second barrier layer 44 may be a WSiN layer or a WN layer.

Then, a mask 64 is formed on the second barrier layer 44. More specifically, a photoresist is formed on the second barrier layer 44. The photoresist is patterned so that a portion of the second barrier layer 44 is exposed from the photoresist. The mask 64 is patterned to include an inclined surface 66 that is inclined so that the width increases toward the second barrier layer 44.

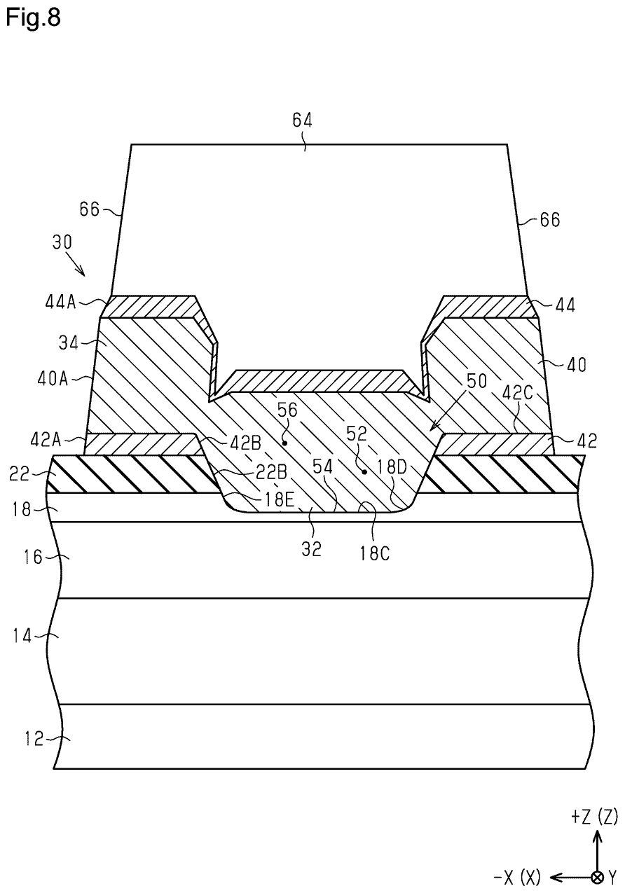

As shown in FIG. 8, the method for manufacturing the nitride semiconductor device 10 includes patterning the first barrier layer 42, the electrode layer 40, and the second barrier layer 44.

More specifically, the second barrier layer 44 exposed from the mask 64 is removed by etching (e.g., dry etching) that uses the mask 64. As a result, the electrode layer 40 is exposed from the mask 64. Then, the electrode layer 40 exposed from the mask 64 is removed by dry etching. As a result, the first barrier layer 42 is exposed from the mask 64. Then, the first barrier layer 42 exposed from the mask 64 is removed by dry etching. Since the mask 64 includes the inclined surface 66, the outer surface 44A of the second barrier layer 44, the outer surface 40A of the electrode layer 40, and the outer surface 42A of the first barrier layer 42 each include an inclined surface. This forms the interconnect 34 of the electrode 30.

The method for manufacturing the nitride semiconductor device 10 includes performing a thermal process. More specifically, the thermal process is performed at a temperature such that the contact 32 of the electrode 30 and the 2DEG 20 (refer to FIG. 1) have a satisfactory ohmic property through the electron supply layer 18. That is, when the thermal process is performed, the contact 32 and the 2DEG 20 form an ohmic contact through the electron supply layer 18. More specifically, nitrogen (N) in the electron supply layer 18 formed of AlGaN is bonded to Ti in the contact 32. As a result, N is removed from the crystal of the electron supply layer 18. That is, vacancies are formed. In this state, the electron supply layer 18 is an n-type. Further, Al, which forms a relatively low Schottky barrier with respect to the n-type electron supply layer 18, diffuses in the interface between the electron supply layer 18 and the contact 32. This decreases the contact resistance. On the other hand, the interconnect 34 includes the first barrier layer 42 and the second barrier layer 44, which are formed from a high melting point metal such as TiN, WSiN, or WN. Thus, the electrode layer 40 is less likely to mutually react with the dielectric layer 22 and the insulation layer 24. This inhibits diffusion of Al from the electrode layer 40 to the dielectric layer 22 and the insulation layer 24. The temperature of the thermal process is set in accordance with the material of the electrode 30. The steps described above form the electrode 30.

Although not shown, the method for manufacturing the nitride semiconductor device 10 includes forming the insulation layer 24. In an example, the insulation layer 24 is a SiO₂ layer formed through PECVD. Alternatively, the insulation layer 24 may be formed through LPCVD. The steps described above manufacture the nitride semiconductor device 10.

### Operation

The operation of the nitride semiconductor device 10 of the first embodiment will now be described.

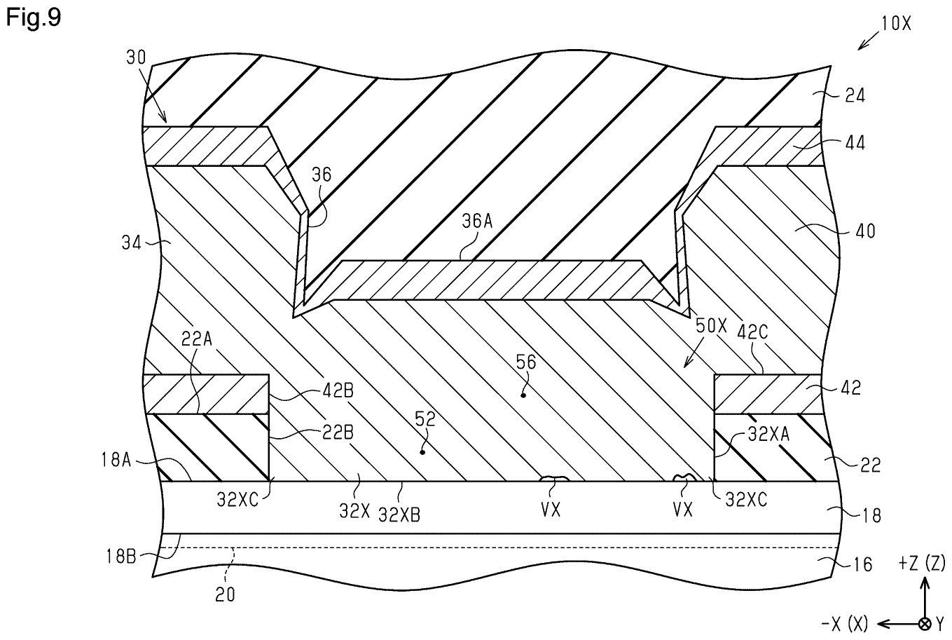

FIG. 9 shows a schematic cross-sectional structure of a comparative example of a nitride semiconductor device (hereafter, referred to as “comparative nitride semiconductor device 10X”). The comparative nitride semiconductor device 10X differs from the nitride semiconductor device 10 (refer to FIG. 1) of the first embodiment in the structure of the opening and the contact of the electrode. In the following description, the opening of the comparative nitride semiconductor device 10X is referred to as an “opening 50X.” The contact of the comparative nitride semiconductor device 10X is referred to as a “contact 32X.” In the comparative nitride semiconductor device 10X, the same reference characters are given to those elements that are the same as the corresponding elements of the nitride semiconductor device 10 of the first embodiment.

As shown in FIG. 9, the opening 50X extends through the dielectric layer 22 to expose the electron supply layer 18. The inner surface 22B of the dielectric layer 22 extends in the Z-axis direction. In the comparative nitride semiconductor device 10X, the recess 54 (refer to FIG. 2) is not formed in the electron supply layer 18. That is, the head surface 18A of the electron supply layer 18 defines the bottom of the opening 50X.

The contact 32X is arranged in the opening 50X. The contact 32X includes an outer surface 32XA in contact with the inner surface 22B of the dielectric layer 22. That is, the outer surface 32XA extends in the Z-axis direction. The contact 32X includes a distal surface 32XB in contact with the head surface 18A of the electron supply layer 18. Thus, the distal surface 32XB and the outer surface 32XA of the contact 32X form a corner 32XC.

A thermal process is performed to form ohmic contact of the contact 32X with the 2DEG 20 through the electron supply layer 18. During this process, stress is produced in the contact 32X due to differences in thermal expansion between the contact 32X and the dielectric layer 22 and the electron supply layer 18. The stress is large particularly in the corner 32XC.

As a result, the contact 32X may deform, and a void VX (empty space) may be formed between the distal surface 32XB of the contact 32X and the head surface 18A of the electron supply layer 18. This increases the contact resistance between the contact 32X and the 2DEG 20 through the electron supply layer 18.

As shown in FIG. 1, in the nitride semiconductor device 10 of the first embodiment, the contact 32 includes the inclined surface 32A, which has a width that decreases toward the distal surface 32B, and the curved surface 32C arranged between the inclined surface 32A and the distal surface 32B. With this structure, when a thermal process is performed, expansion force of the contact 32 is dispersed by the inclined surface 32A and the curved surface 32C. Thus, stress produced in the contact 32 is mitigated. This limits deformation of the contact 32, thereby limiting formation of the void VX between the distal surface 32B of the contact 32 and the electron supply layer 18. Accordingly, an increase in the contact resistance between the contact 32 and the 2DEG 20 through the electron supply layer 18 is limited.

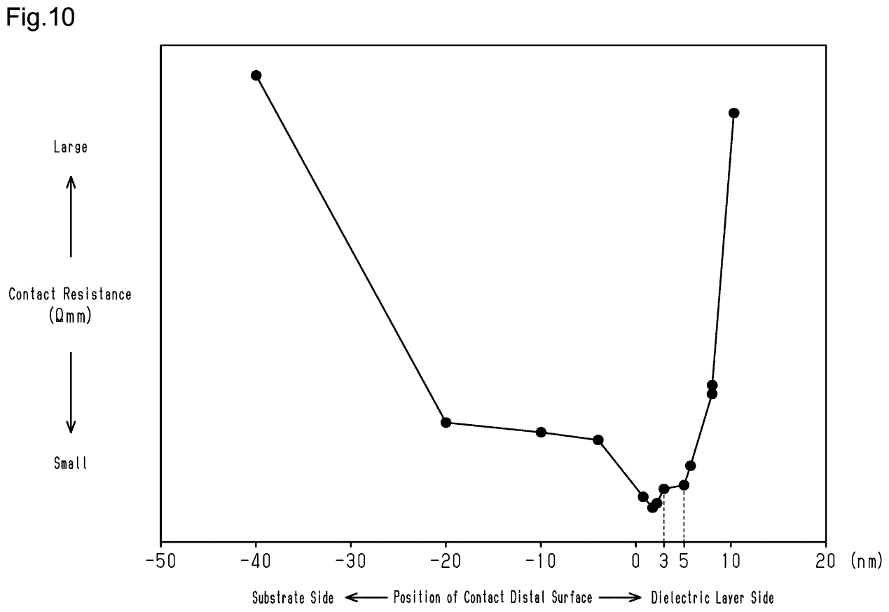

FIG. 10 is a graph showing the relationship between the contact resistance and the position of the distal surface 32B of the contact 32 in the Z-axis direction. The horizontal axis represents the position of the distal surface 32B of the contact 32 in the Z-axis direction. The vertical axis represents the contact resistance (Ω mm). The range of the horizontal axis between “0 nm” and “10 nm” indicates a range in which the electron supply layer 18 is formed in the Z-axis direction. The horizontal axis at “0 nm” indicates a position of the back surface 18B of the electron supply layer 18. The horizontal axis at “10 nm” indicates a position of the head surface 18A of the electron supply layer 18. Hence, “5 nm” indicates the center of the electron supply layer 18 in the Z-axis direction. The negative range of the horizontal axis indicates a range in which the electron transit layer 16 is formed in the Z-axis direction. More specifically, the negative range of the horizontal axis indicates that the contact 32 extends through the electron supply layer 18 and is in contact the electron transit layer 16.

As shown in FIG. 10, when the distal surface 32B of the contact 32 is located even slightly beyond the head surface 18A of the electron supply layer 18 toward the back surface 18B, the contact resistance is significantly decreased. That is, when the recess 54 of the opening 50 is formed in the electron supply layer 18, the contact resistance is significantly decreased. In other words, when the recess 54 is not formed in the electron supply layer 18, the contact resistance is increased.

When the through portion 52 is formed in the dielectric layer 22 by dry etching, fluorine is typically used as a reaction gas. Fluorine remains on the head surface 18A of the electron supply layer 18. The contact resistance may be increased by the fluorine.

When the recess 54 is formed in the electron supply layer 18, the remaining fluorine will be removed together with the head surface 18A of the electron supply layer 18. Thus, the contact resistance is decreased. In the first embodiment, the opening 50 includes the recess 54 that is formed in the electron supply layer 18. The distal surface 32B of the contact 32 is in contact with the recess bottom surface 18C of the recess 54. Thus, the contact resistance is decreased.

Furthermore, as shown in FIG. 10, the contact resistance is decreased particularly when the position of the distal surface 32B of the contact 32 is in a range of 0 nm or greater and less than 3 nm. For example, when the position of the distal surface 32B of the contact 32 is in a range of 1.5 nm or greater and 3 nm or less, the contact resistance decreases as the distal surface 32B of the contact 32 becomes closer to the position of 1.5 nm. The contact resistance increases as the distal surface 32B of the contact 32 becomes closer to the electron transit layer 16 from the position of 1.5 nm. The contact resistance when the distal surface 32B of the contact 32 is located at the position of 0 nm is substantially equal to the contact resistance when the distal surface 32B of the contact 32 is located at the position of 5 nm. Therefore, the contact resistance is at a minimum when the distal surface 32B of the contact 32 is at the position of 1.5 nm.

### Advantages

The nitride semiconductor device 10 of the first embodiment obtains the following advantages.

(1-1) The nitride semiconductor device 10 includes the electron transit layer 16, the electron supply layer 18 formed on the electron transit layer 16 and having a larger bandgap than the electron transit layer 16, the dielectric layer 22 formed on the electron supply layer 18, and the electrode 30 including the contact 32 in electrical contact with the electron supply layer 18 through the opening 50 extending through at least the dielectric layer 22. The contact 32 includes the inclined surface 32A, which is inclined so that the width of the contact 32 decreases toward the electron transit layer 16, the distal surface 32B in contact with the surface defining the bottom of the opening 50, and the curved surface 32C arranged between the distal surface 32B and the inclined surface 32A and being convex toward the electron transit layer 16.

With this structure, during the thermal process performed in the manufacturing of the nitride semiconductor device 10, stress produced in the electrode 30 is mitigated by the inclined surface 32A and the curved surface 32C of the contact 32. Thus, formation of the void VX between the contact 32 and the electron supply layer 18 is limited. Accordingly, an increase in the contact resistance between the electrode 30 (the contact 32) and the 2DEG 20 through the electron supply layer 18 is limited. As described above, when formation of the void VX is limited, the ohmic contact structure of the electrode 30 with the 2DEG 20 will have a stable low contact resistance.

(1-2) The opening 50 includes the through portion 52, which extends through the dielectric layer 22, and the recess 54, which is disposed in the electron supply layer 18 and continuous with the through portion 52. The opening 50 extends through the dielectric layer 22 and is formed in at least a portion of the electron supply layer 18. The inclined surface 32A of the contact 32 includes the first part 32AA in contact with the dielectric layer 22 and the second part 32AB in contact with the electron supply layer 18. The curved surface 32C of the contact 32 is in contact with the electron supply layer 18.

When fluorine is used to perform dry etching on the dielectric layer 22, the fluorine may remain on the head surface 18A of the electron supply layer 18. With this structure described above, the fluorine is removed when the recess 54 is formed in the electron supply layer 18. Thus, the contact resistance between the contact 32 and the 2DEG 20 through the electron supply layer 18 is decreased.

(1-3) The distal surface 32B of the contact 32 is located closer to the electron transit layer 16 than the center of the electron supply layer 18 in the thickness-wise direction (Z-direction) of the electron supply layer 18 is.

With this structure, as shown in FIG. 10, when the distal surface 32B of the contact 32 is located closer to the electron transit layer 16 than the center of the electron supply layer 18 in the Z-axis direction is, the contact resistance between the contact 32 and the 2DEG 20 through the electron supply layer 18 is further decreased.

(1-4) The inclination angle of the first part 32AA of the inclined surface 32A of the contact 32 with respect to the thickness-wise direction (Z-axis direction) of the electron transit layer 16 is equal to the inclination angle of the second part 32AB with respect to the Z-axis direction.

With this structure, when a thermal process is performed in the manufacturing of the nitride semiconductor device 10, thermal expansion force of the contact 32 is dispersed to the inner surface 22B of the dielectric layer 22 and the recess inclined surface 18E of the electron supply layer 18. Since the inclination angles are the same, the dispersed forces are less likely to affect each other. This mitigates stress produced in the contact 32 caused by reaction forces of the dielectric layer 22 and the electron supply layer 18 with the contact 32. As a result, formation of the void VX between the contact 32 and the electron supply layer 18 is limited, thereby limiting an increase in the contact resistance between the electrode 30 (the contact 32) and the 2DEG 20 through the electron supply layer 18.

(1-5) The inclination angle of the first part 32AA of the inclined surface 32A with respect to the Z-axis direction and the inclination angle of the second part 32AB with respect to the Z-axis direction are each 10° or greater and 20° or less. In other words, the inclination angle of the inner surface 22B of the dielectric layer 22 with respect to the Z-axis direction and the inclination angle of the recess inclined surface 18E of the recess 54 with respect to the Z-axis direction are each 10° or greater and 20° or less.

With this structure, since the inclination angles are each 10° or greater and 20° or less, formation of a micro-trench shape between the recess inclined surface 18E and the recess bottom surface 18C is limited. Accordingly, the curved surface 32C is formed between the inclined surface 32A and the distal surface 32B of the contact 32 in contact with the recess 54. This mitigates stress produced in the electrode 30 during the thermal process performed in the manufacturing of the nitride semiconductor device 10.

(1-6) In the contact 32, the first part 32AA and the second part 32AB of the inclined surface 32A are continuous and flush with each other.

This structure avoids production of stress in the contact 32 caused by a step in comparison to a structure in which the step is formed between the first part 32AA and the second part 32AB. Thus, stress produced in the contact 32 is mitigated.

(1-7) The electrode 30 includes the interconnect 34 disposed on the dielectric layer 22. The length L2 of the interconnect 34 in the width-wise direction (X-axis direction) is at least twice the length L1 of the distal portion 32P of the contact 32 in the width-wise direction.

This structure increases the heat capacity of the electrode 30 including the interconnect 34 and the contact 32. Thus, during the thermal process performed in the manufacturing of the nitride semiconductor device 10, stress produced in the electrode 30 is mitigated.

(1-8) The interconnect 34 includes the first barrier layer 42 in contact with the dielectric layer 22.

In this structure, the interconnect 34 and the dielectric layer 22 are separated by the first barrier layer 42. This limits dispersion of Al in the dielectric layer 22 caused by a mutual reaction between an Al component of the electrode 30 and a Si component of the dielectric layer 22.

(1-9) The first barrier layer 42 includes any of TiN, WSiN, and WN.

This structure limits dispersion of Al included in the electrode 30 to the dielectric layer 22. The same advantage is obtained even when the first barrier layer 42 has a structure in which multiple layers including any of TIN, WSiN, and WN are stacked.

(1-10) The interconnect 34 includes the second barrier layer 44 located at a side opposite to the first barrier layer 42.

In this structure, the interconnect 34 and the insulation layer 24 are separated by the second barrier layer 44. This limits dispersion of Al in the insulation layer 24 caused by a mutual reaction between an Al component of the electrode 30 and a Si component of the insulation layer 24.

(1-11) The second barrier layer 44 includes any of TIN, WSiN, and WN.

This structure limits dispersion of Al included in the electrode 30 to the insulation layer 24. The same advantage is obtained even when the second barrier layer 44 has a structure in which multiple layers including any of TiN, WSiN, and WN are stacked.

(1-12) The electrode layer 40 includes at least Ti, Al, and Cu.

With this structure, when the electrode layer 40 includes Ti, Ti removes nitrogen (N) from the electron supply layer 18 formed of AlGaN to form a vacancy in the electron supply layer 18. The vacancy is of an n-type and thus decreases the contact resistance of the electrode 30 with the 2DEG 20.

When the electrode layer 40 includes Al, Al has a low Schottky barrier with respect to the electron supply layer 18 formed of AlGaN. In addition, during the thermal process performed in the manufacturing of the nitride semiconductor device 10, Al disperses to the recess 54 of the electron supply layer 18. This decreases the contact resistance. Further, when approximately 1% or less of Cu having a larger atomic number than Al to Al and a large current flows through the electrode 30, electromigration is less likely to occur.

(1-13) The electron supply layer 18 includes an AlₓGa₁₋ₓN layer (0.2≤x≤0.3).

With this structure, when the composition ratio of Al is 0.2 or greater and 0.3 or less, the recess 54 including the recess inclined surface 18E, the recess curved surfaces 18D, and the recess bottom surface 18C is formed in the electron supply layer 18. This limits an increase in the contact resistance between the electrode 30 (the contact 32) and the 2DEG 20 through the electron supply layer 18.

(1-14) The arc length of the curved surface 32C in the contact 32 is greater than the arc length of the connection part 38 (refer to FIG. 2) between the contact 32 and the interconnect 34.

With this structure, the curved surface 32C increases the effect of mitigating stress produced in the electrode 30.

### Second Embodiment

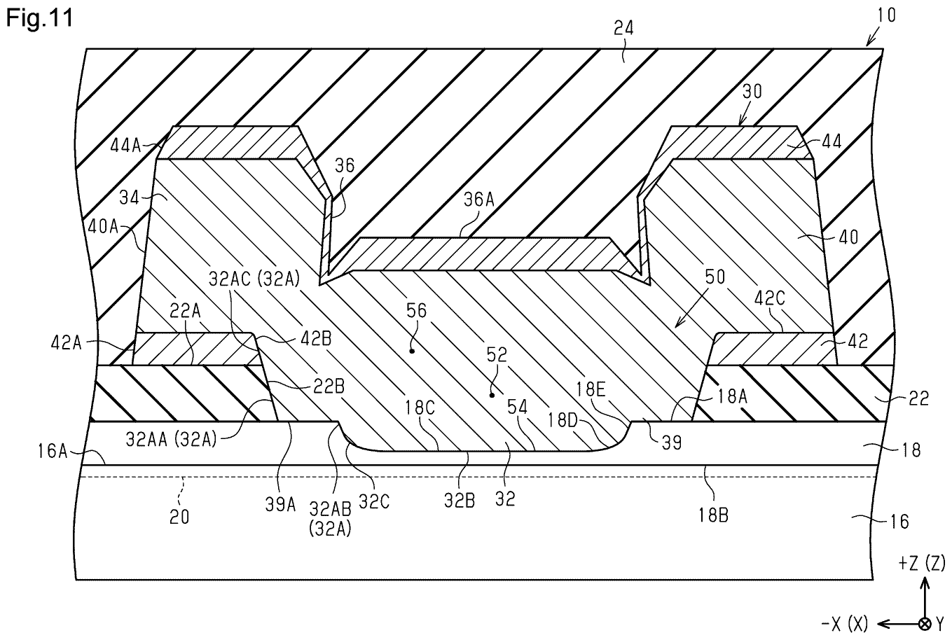

The structure of a second embodiment of the nitride semiconductor device 10 will now be described with reference to FIG. 11. The second embodiment of the nitride semiconductor device 10 differs from the first embodiment of the nitride semiconductor device 10 mainly in the structure of the opening 50 and the contact 32 of the electrode 30. In the following description, differences from the first embodiment of the nitride semiconductor device 10 will be described in detail. Same reference characters are given to those elements that are the same as the corresponding elements of the first embodiment of the nitride semiconductor device 10. Such elements will not be described in detail.

As shown in FIG. 11, in the second embodiment, the opening 50 is disposed to expose the head surface 18A of the electron supply layer 18. That is, in the second embodiment, the inner surface 22B of the dielectric layer 22, defining the through portion 52, is not continuous and flush with the recess inclined surface 18E of the electron supply layer 18, defining the recess 54. The inner surface 22B of the dielectric layer 22 has an edge that is in contact with the head surface 18A of the electron supply layer 18 and located outward in the X-axis direction than an edge of the recess inclined surface 18E of the electron supply layer 18 in contact with the head surface 18A of the electron supply layer 18. Thus, the head surface 18A of the electron supply layer 18 is disposed between the inner surface 22B of the dielectric layer 22 and the recess inclined surface 18E. That is, the head surface 18A of the electron supply layer 18 disposed between the inner surface 22B of the dielectric layer 22 and the recess inclined surface 18E joins the inner surface 22B of the dielectric layer 22 to the recess inclined surface 18E. In the second embodiment, the width of the through portion 52 is greater than that of the through portion 52 in the first embodiment. In the second embodiment, the inclination surface of the inner surface 22B of the dielectric layer 22 with respect to the Z-axis direction and the inclination surface of the recess inclined surface 18E with respect to the Z-axis direction are the same as in the first embodiment.

The contact 32 of the electrode 30 includes a step 39 disposed between the first part 32AA and the second part 32AB of the inclined surface 32A. The step 39 is in contact with the head surface 18A of the electron supply layer 18 that is in contact with the dielectric layer 22. More specifically, the step 39 includes a step surface 39A opposing the head surface 18A of the electron supply layer 18. The step surface 39A is flat and parallel to an XY-plane. The step surface 39A is in contact with the head surface 18A of the electron supply layer 18. The distal surface 32B and the curved surface 32C of the contact 32 are the same as the distal surface 32B and the curved surface 32C in the first embodiment.

A method for manufacturing the nitride semiconductor device 10 will now be described. Differences from the method for manufacturing the nitride semiconductor device 10 of the first embodiment will be described.

The method for manufacturing the nitride semiconductor device 10 of the second embodiment differs in the process for forming the recess 54 in the electron supply layer 18. More specifically, first, a mask (not shown) is formed on the electron supply layer 18 exposed by the through portion 52 of the dielectric layer 22. The mask is formed through a photoresist and patterning in the same manner as the mask 60 (refer to FIG. 5). The mask has an opening that is smaller in width than the through portion 52. The opening exposes the electron supply layer 18. A portion of the electron supply layer 18 is removed from a position corresponding to the opening of the mask by etching (e.g., dry etching) that uses the mask. In this case, in the same manner as the first embodiment, the etching condition is set so that the recess 54, that is, the recess bottom surface 18C, the recess curved surfaces 18D, and the recess inclined surface 18E, is formed. Since the opening (not shown) in the mask is tapered, the recess inclined surface 18E includes an inclined surface so that the width of the recess 54 decreases toward the electron transit layer 16. The mask for etching the dielectric layer 22 and the mask for etching the electron supply layer 18 are formed under the same condition. This allows the inclination angle of the recess inclined surface 18E with respect to the Z-axis direction to be equal to the inclination angle of the inner surface 22B of the dielectric layer 22 with respect to the Z-axis direction. The inclination angles of the recess inclined surface 18E and the inner surfaces 22B and 42B with respect to the Z-axis direction are each 10° or greater and 20° or less for instance, in an example, 15°. After the recess 54 is formed, the mask is removed.

### Advantages

The nitride semiconductor device 10 of the second embodiment obtains the following advantage in addition to the advantages (1-1) to (1-5) and (1-7) to (1-14) of the first embodiment.

(2-1) The contact 32 includes a step 39 disposed between the first part 32AA and the second part 32AB of the inclined surface 32A. The step 39 is in contact with the head surface 18A of the electron supply layer 18 that is in contact with the dielectric layer 22.

This structure increases the area of contact of the contact 32 with the electron supply layer 18. Thus, a large current is supplied from the contact 32 to the electron supply layer 18 at a low resistance. For example, when the nitride semiconductor device 10 is applied to a power device, power consumption is reduced by the ohmic contact structure described above.

### Third Embodiment

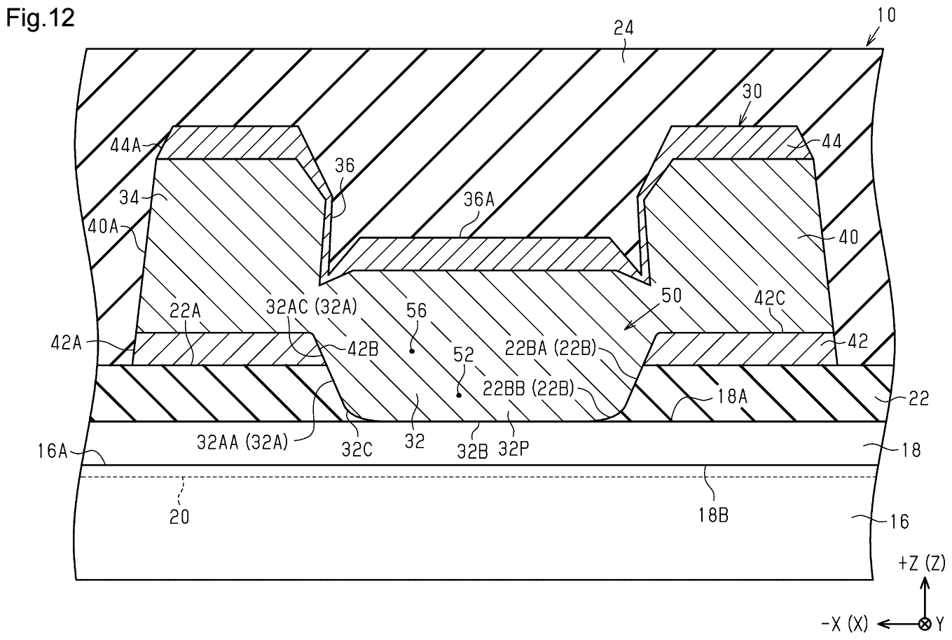

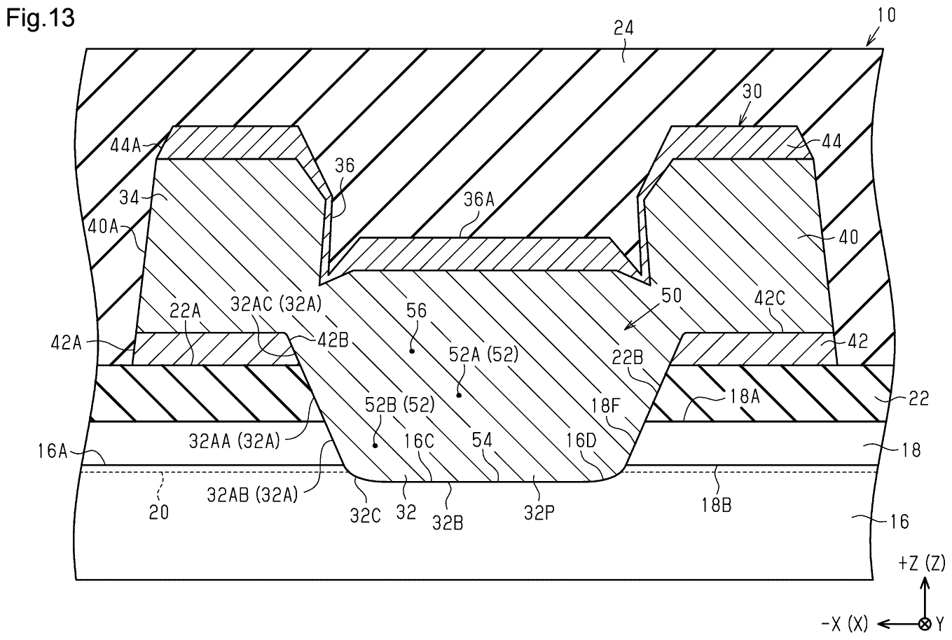

The structure of a third embodiment of the nitride semiconductor device 10 will now be described with reference to FIG. 12. The third embodiment of the nitride semiconductor device 10 differs from the first embodiment of the nitride semiconductor device 10 mainly in the structure of the opening 50 and the contact 32 of the electrode 30. In the following description, differences from the first embodiment of the nitride semiconductor device 10 will be described in detail. Same reference characters are given to those elements that are the same as the corresponding elements of the first embodiment of the nitride semiconductor device 10. Such elements will not be described in detail.

As shown in FIG. 12, in the third embodiment, the opening 50 does not include the recess 54 (refer to FIG. 1). That is, the opening 50 includes the barrier through portion 56 and the through portion 52. The bottom of the opening 50 is defined by the head surface 18A of the electron supply layer 18.

In the third embodiment, the shape of the through portion 52 also differs. More specifically, the inner surface 22B of the dielectric layer 22 defining the through portion 52 includes a dielectric-side inclined surface 22BA and a dielectric-side curved surface 22BB disposed between the dielectric-side inclined surface 22BA and the head surface 18A of the electron supply layer 18.

The dielectric-side inclined surface 22BA is continuous and flush with the inner surface 42B of the first barrier layer 42 defining the barrier through portion 56. The inclination angle of the dielectric-side inclined surface 22BA with respect to the Z-axis direction is equal to the inclination angle of the inner surface 42B with respect to the Z-axis direction. The inclination angles are each 10° or greater and 20° or less for instance, in an example, 15°, in the same manner as the first embodiment.

The dielectric-side curved surface 22BB is convex toward the electron supply layer 18. The dielectric-side curved surface 22BB has the same shape as the recess curved surfaces 18D of the first embodiment. The arc length of the dielectric-side curved surface 22BB is greater than the arc length of the connection part 38 (refer to FIG. 2) between the contact 32 and the interconnect 34.

The distal surface 32B of the contact 32 of the electrode 30 is flush with the upper surface of the electron supply layer 18 (the head surface 18A of the electron supply layer 18) that is in contact with the dielectric layer 22. The distal surface 32B is in contact with the head surface 18A of the electron supply layer 18.

The inclined surface 32A of the contact 32 does not include the second part 32AB. That is, the inclined surface 32A includes the first part 32AA and the third part 32AC. The curved surface 32C is located closer to the first barrier layer 42 than the head surface 18A of the electron supply layer 18 is. In the third embodiment, the curved surface 32C is in contact with the dielectric layer 22. More specifically, the curved surface 32C is in contact with the dielectric-side curved surface 22BB. Thus, the arc length of the curved surface 32C is greater than the arc length of the connection part 38 (refer to FIG. 2).

In the third embodiment, the distal portion 32P of the contact 32 includes the distal surface 32B and the curved surface 32C. The relationship of the length of the interconnect 34 in the width-wise direction (the X-axis direction) with the length of the distal portion 32P of the contact 32 in the width-wise direction is the same as that of the first embodiment.

### Advantages

The nitride semiconductor device 10 of the third embodiment obtains the following advantage in addition to the advantages (1-1) and (1-7) to (1-14) of the first embodiment.

(3-1) The distal surface 32B of the contact 32 is flush with the head surface 18A of the electron supply layer 18 that is in contact with the dielectric layer 22. The curved surface 32C is in contact with the dielectric layer 22.

With this structure, during the thermal process performed in the manufacturing of the nitride semiconductor device 10, stress produced in the electrode 30 is mitigated by the inclined surface 32A (first part 32AA) and the curved surface 32C of the contact 32. Thus, the void VX is less likely to be formed between the distal surface 32B and the electron supply layer 18. Accordingly, an increase in the contact resistance between the electrode 30 (the contact 32) and the 2DEG 20 through the electron supply layer 18 is limited. As described above, when formation of the void VX is limited, the ohmic contact structure of the electrode 30 with the 2DEG 20 will have a stable low contact resistance.

### Fourth Embodiment

The structure of a fourth embodiment of the nitride semiconductor device 10 will now be described with reference to FIG. 13. The fourth embodiment of the nitride semiconductor device 10 differs from the first embodiment of the nitride semiconductor device 10 mainly in the structure of the contact 32 of the electrode 30. In the following description, differences from the first embodiment of the nitride semiconductor device 10 will be described in detail. Same reference characters are given to those elements that are the same as the corresponding elements of the first embodiment of the nitride semiconductor device 10. Such elements will not be described in detail.

As shown in FIG. 13, in the fourth embodiment, the opening 50 extends through the dielectric layer 22 and the electron supply layer 18. The opening 50 is formed in at least a portion of the electron transit layer 16. In the fourth embodiment, the through portion 52 of the opening 50 extends through the dielectric layer 22 and the electron supply layer 18. The recess 54 is continuous with the through portion 52 and is disposed in the electron transit layer 16.

The through portion 52 includes a first through portion 52A extending through the dielectric layer 22 and a second through portion 52B extending through the electron supply layer 18.

The first through portion 52A has the same structure as the through portion 52 (refer to FIG. 1) of the first embodiment. The relationship of the inner surface 22B of the dielectric layer 22, defining the first through portion 52A, and the inner surface 42B of the first barrier layer 42, defining the barrier through portion 56, is the same as that of the first embodiment.

The second through portion 52B is defined by an inner surface 18F that defines the opening in the electron supply layer 18. The inner surface 18F is inclined so that the opening width of the second through portion 52B decreases toward the buffer layer 14 (refer to FIG. 1). The opening width of the second through portion 52B is defined by the dimension of the second through portion 52B in the X-axis direction. In the fourth embodiment, the inclination angle of the inner surface 18F with respect to the Z-axis direction is equal to the inclination angle of the inner surface 22B of the dielectric layer 22 with respect to the Z-axis direction. The inner surface 18F is continuous and flush with the inner surface 22B. In the same manner as the first embodiment, the inclination angle of the inner surface 18F with respect to the Z-axis direction and the inclination angle of the inner surface 22B of the dielectric layer 22 with respect to the Z-axis direction are each 10° or greater and 20° or less and, in an example, 15°.

The recess 54 includes a recess bottom surface 16C formed in the electron transit layer 16 and recess curved surfaces 16D formed on two ends of the recess bottom surface 16C in the X-axis direction. Thus, the recess 54 does not include a recess inclined surface, which differs from the first embodiment. The recess bottom surface 16C may refer to a bottom surface of the electron transit layer 16 that is in contact with the distal surface 32B of the contact 32.

The recess bottom surface 16C is disposed closer to the head surface 16A of the electron transit layer 16 than the back surface 16B is. In the fourth embodiment, the recess bottom surface 16C is disposed closer to the head surface 16A than the center of the electron transit layer 16 in the thickness-wise direction (Z-axis direction) is. In an example, the distance between the head surface 16A and the recess bottom surface 16C of the electron transit layer 16 in the Z-axis direction, that is, the depth of the recess 54, is less than or equal to 20 nm. The recess bottom surface 16C extends in the X-axis direction. The recess bottom surface 16C defines the bottom of the opening 50.

The recess curved surfaces 16D are convex toward the buffer layer 14. Thus, the recess curved surfaces 16D have a center of curvature located toward the electron supply layer 18 with respect to the recess bottom surface 16C. The recess curved surfaces 16D has the same shape as the first embodiment of the recess curved surfaces 18D (refer to FIG. 1). The arc length of the recess curved surfaces 16D is greater than the arc length of the connection part 38 (refer to FIG. 2) between the contact 32 and the interconnect 34.

The contact 32 of the electrode 30 extends in the opening 50 through the dielectric layer 22 and the electron supply layer 18. The contact 32 reaches the electron transit layer 16. In the fourth embodiment, the inclined surface 32A of the contact 32 includes the first part 32AA in contact with the dielectric layer 22 and the second part 32AB in contact with the electron supply layer 18. The inclined surface 32A further includes a third part 32AC in contact with the first barrier layer 42.

The first part 32AA of the fourth embodiment has the same structure as the first part 32AA of the first embodiment. In the fourth embodiment, the second part 32AB is in contact with the entirety of the inner surface 18F of the electron supply layer 18, which differs from the second part 32AB of the first embodiment. The first part 32AA is continuous and flush with the second part 32AB. The inclination angle of the first part 32AA with respect to the Z-axis direction is equal to the inclination angle of the second part 32AB with respect to the Z-axis direction. The inclination angle of the first part 32AA with respect to the Z-axis direction and the inclination angle of the second part 32AB with respect to the Z-axis direction are each 10° or greater and 20° or less. In the fourth embodiment, the inclination angle of the first part 32AA with respect to the Z-axis direction and the inclination angle of the second part 32AB with respect to the Z-axis direction are each 15°.

The curved surface 32C of the contact 32 is in contact with at least the electron transit layer 16. In the fourth embodiment, the curved surface 32C is located closer to the buffer layer 14 than the back surface 18B of the electron supply layer 18 is. In the same manner as the first embodiment, the arc length of the curved surface 32C is greater than the arc length of the connection part 38 between the contact 32 and the interconnect 34.

In the fourth embodiment, the distal portion 32P of the contact 32 includes the distal surface 32B and the curved surface 32C. In other words, the distal portion 32P fills the recess 54 disposed in the electron transit layer 16. The relationship of the length of the interconnect 34 in the width-wise direction (the X-axis direction) with the length of the distal portion 32P of the contact 32 in the width-wise direction is the same as that of the first embodiment.

In the fourth embodiment, the entirety of the curved surface 32C is in contact with the electron transit layer 16. However, there is no limitation to such a configuration. In an example, the curved surface 32C may be partially in contact with the electron supply layer 18. In this case, a recess curved surface may be formed on a portion of the electron supply layer 18. In other words, the recess curved surface is formed on the electron supply layer 18 and the electron transit layer 16.

### Advantages

The nitride semiconductor device 10 of the fourth embodiment obtains the following advantages.

(4-1) The opening 50 includes the through portion 52, which extends through the dielectric layer 22 and the electron supply layer 18, and the recess 54, which is disposed in the electron transit layer 16 and continuous with the through portion 52. The opening 50 extends through the dielectric layer 22 and the electron supply layer 18 and is formed in at least a portion of the electron transit layer 16. The contact 32 extends in the opening 50 through the dielectric layer 22 and the electron supply layer 18 and reaches the electron transit layer 16. The inclined surface 32A of the contact 32 includes the first part 32AA in contact with the dielectric layer 22 and the second part 32AB in contact with the electron supply layer 18. The curved surface 32C of the contact 32 is in contact with at least the electron transit layer 16.

With this structure, during the thermal process performed in the manufacturing of the nitride semiconductor device 10, stress produced in the electrode 30 is mitigated by the inclined surface 32A and the curved surface 32C of the contact 32. Thus, a void VX is less likely to be formed between the distal surface 32B and the electron transit layer 16. Accordingly, the contact resistance between the electrode 30 (contact 32) and the 2DEG 20 is less likely to increase. As described above, when formation of a void VX is limited, the ohmic contact structure of the electrode 30 with the 2DEG 20 will have a stable low contact resistance.

(4-2) The electron transit layer 16 includes the head surface 16A, which is in contact with the electron supply layer 18, and the recess bottom surface 16C, which corresponds to the bottom surface in contact with the distal surface 32B of the contact 32. The distance between the head surface 16A and the recess bottom surface 16C of the electron transit layer 16 in the thickness-wise direction (Z-axis direction) of the electron transit layer 16 is less than or equal to 20 nm.

With this structure, as shown by the graph in FIG. 10, the contact resistance is small when the distal surface 32B of the contact 32 is located at a position shallower than 20 nm from the head surface 16A of the electron transit layer 16. Therefore, when the distance between the head surface 16A and the recess bottom surface 16C of the electron transit layer 16 is less than or equal to 20 nm, the contact resistance is decreased.

In addition, for example, when the electron supply layer 18 is thin, it is difficult to form the recess 54 in the electron supply layer 18. In this case, the recess 54 is readily formed in the electron transit layer 16. Thus, the manufacturing process of the nitride semiconductor device 10 is stabilized.

### Fifth Embodiment

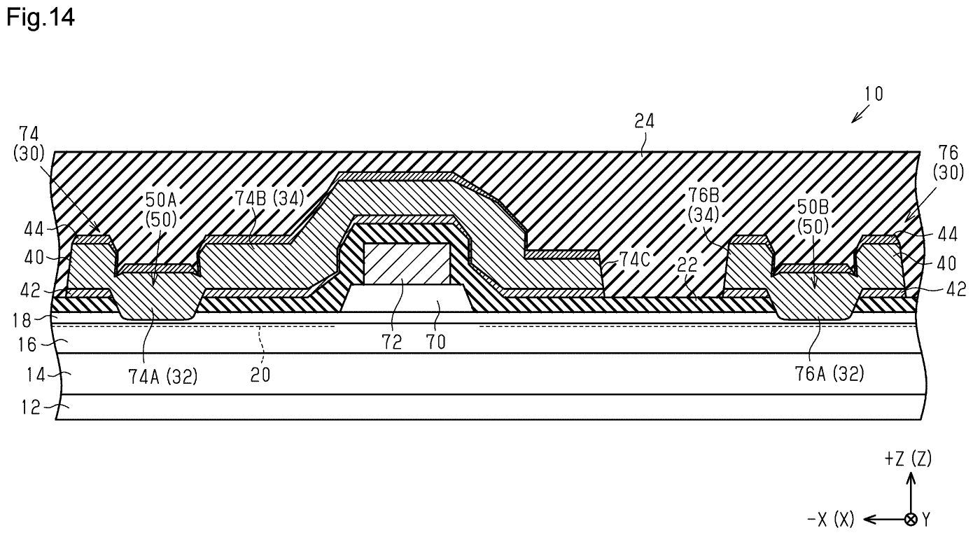

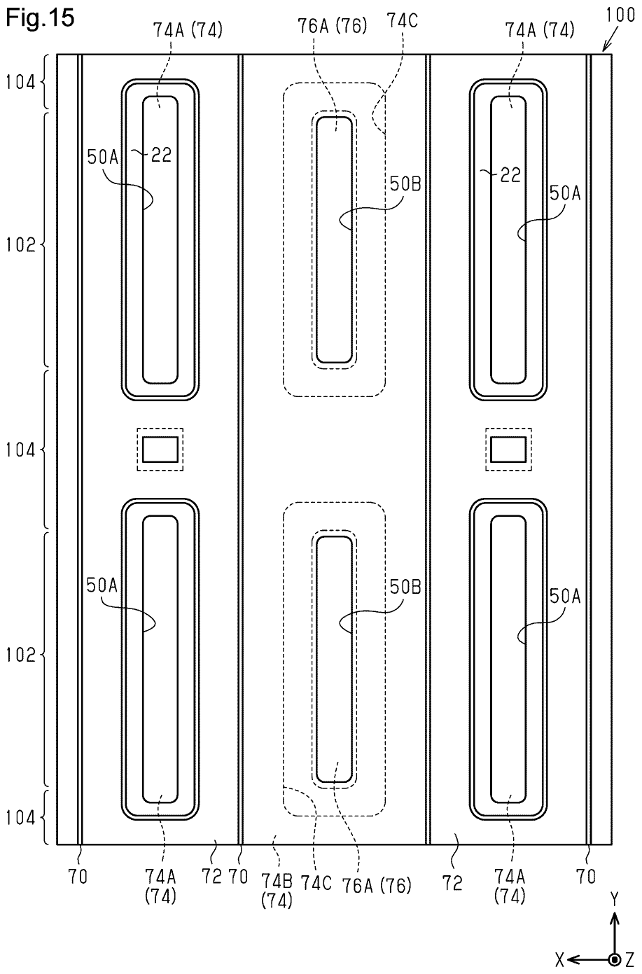

The structure of a fifth embodiment of the nitride semiconductor device 10 will now be described with reference to FIGS. 14 and 15. In the fifth embodiment, the nitride semiconductor device 10 is a high electron mobility transistor (HEMT), which differs from the nitride semiconductor device 10 of the first embodiment. In the following description, differences from the first embodiment of the nitride semiconductor device 10 will be described in detail. Same reference characters are given to those elements that are the same as the corresponding elements of the first embodiment of the nitride semiconductor device 10. Such elements will not be described in detail.

As shown in FIG. 14, in the fifth embodiment, the nitride semiconductor device 10 includes a gate layer 70 formed on the electron supply layer 18 and a gate electrode 72 formed on the gate layer 70. The nitride semiconductor device 10 further includes a source electrode 74 and a drain electrode 76.

The gate layer 70 is composed of a nitride semiconductor having a bandgap that is smaller than that of the electron supply layer 18 and including an acceptor impurity. The gate layer 70 may be formed from any material having a bandgap that is smaller than that of the electron supply layer 18, which is, for example, an AlGaN layer. In an example, the gate layer 70 is a GaN layer (p-type GaN layer) doped with an acceptor impurity. The acceptor impurity may contain at least one of zinc (Zn), magnesium (Mg), and carbon (C). The maximum concentration of the acceptor impurity in the gate layer 70 is, for example, 1×10¹⁸ cm⁻³ or greater and 1×10²⁰ cm⁻³ or less.

As described above, the acceptor impurity included in the gate layer 70 increases the energy levels of the electron transit layer 16 and the electron supply layer 18. As a result, in a region immediately below the gate layer 70, the energy level of the conduction band of the electron transit layer 16 in the vicinity of the heterojunction interface between the electron transit layer 16 and the electron supply layer 18 is substantially equal to or greater than the Fermi level. Therefore, when no voltage is applied to the gate electrode 72, that is, in the zero bias state, the 2DEG 20 is not formed in the electron transit layer 16 in the region immediately below the gate layer 70. On the other hand, in a region other than the region immediately below the gate layer 70, the 2DEG 20 is formed in the electron transit layer 16.

In this manner, the gate layer 70, which is doped with the acceptor impurity, depletes the 2DEG 20 in the region immediately below the gate layer 70. This results in a normally-off operation of the nitride semiconductor device 10. The application of an appropriate on-voltage to the gate electrode 72 will form a channel with the 2DEG 20 in the electron transit layer 16 in the region immediately below the gate electrode 72 to electrically connect the source and drain.

The gate electrode 72 is composed of one or more metal layers. In an example, the gate electrode 72 is a TiN layer. Alternatively, the gate electrode 72 may be formed by a first metal layer of a material containing Ti and a second metal layer formed from a material containing TiN. The gate electrode 72 has a thickness in a range of, for example, 50 nm to 200 nm. The gate electrode 72 may form a Schottky junction with the gate layer 70.

In the fifth embodiment, the dielectric layer 22 covers the electron supply layer 18, the gate layer 70, and the gate electrode 72. In the fifth embodiment, the opening 50 includes a source opening 50A and a drain opening 50B. The source opening 50A and the drain opening 50B are each separated from the gate layer 70. The gate layer 70 is located between the source opening 50A and the drain opening 50B in the X-axis direction. More specifically, the gate layer 70 is located between the source opening 50A and the drain opening 50B closer to the source opening 50A than to the drain opening 50B. The structure of the source opening 50A and the drain opening 50B is the same as the structure of the opening 50 in the first embodiment.

In the fifth embodiment, the electrode 30 includes electrodes including the source electrode 74 and the drain electrode 76.

The source electrode 74 is electrically connected to the electron supply layer 18 through the source opening 50A. The source electrode 74 includes a contact 74A and a field plate 74B continuous with the contact 74A. The contact 74A is a portion embedded in the source opening 50A. The contact 74A corresponds to the contact 32 of the electrode 30. Thus, the contact 74A and the contact 32 have the same structure. The field plate 74B covers the dielectric layer 22 and includes an end 74C located between the drain opening 50B and the gate layer 70 in the X-axis direction in plan view. The field plate 74B is separate from the drain electrode 76 formed in the drain opening 50B. The field plate 74B extends from the contact 74A to the end 74C toward the drain electrode 76 along the surface 22A of the dielectric layer 22. When no gate voltage is applied to the gate electrode 72, that is, in the zero bias state, the field plate 74B reduces the concentration of an electric field in the vicinity of the end of the gate electrode 72. Although differing in shape, the field plate 74B corresponds to the interconnect 34 of the electrode 30. Thus, the field plate 74B has a stacked structure of the electrode layer 40, the first barrier layer 42, and the second barrier layer 44.

The drain electrode 76 is electrically connected to the electron supply layer 18 through the drain opening 50B. The drain electrode 76 includes a contact 76A and an interconnect 76B in contact with the contact 76A. The contact 76A is a portion embedded in the drain opening 50B. The contact 76A corresponds to the contact 32 of the electrode 30. Thus, the contact 76A and the contact 32 have the same structure. The interconnect 76B corresponds to the interconnect 34 of the electrode 30. Thus, the interconnect 76B has a stacked structure of the electrode layer 40, the first barrier layer 42, and the second barrier layer 44.

The electrode layer 40 of each of the source electrode 74 and the drain electrode 76 is composed of one or more metal layers (for example, Ti, Al, TiN). The source electrode 74 and the drain electrode 76 are in contact with the electron supply layer 18 through the source opening 50A and the drain opening 50B, respectively. Thus, the source electrode 74 and the drain electrode 76 are each in ohmic contact with the 2DEG 20. The insulation layer 24 covers the source electrode 74 and the drain electrode 76.

FIG. 15 shows a planar structure of an exemplary formation pattern 100 in the nitride semiconductor device 10 of the fifth embodiment. To facilitate understanding, in FIG. 15, the same reference characters are given to those components that are the same as the corresponding components shown in FIG. 14. The drain electrode 76, the source electrode 74, and the dielectric layer 22 are transparently illustrated so that components in layers underneath (for example, gate layer 70) are visible. The source electrode 74 and the drain electrode 76 are shown by broken lines indicating only the outer edges. In the dielectric layer 22, only the source opening 50A and the drain opening 50B are shown.

As shown in FIG. 15, the formation pattern 100 includes active regions 102 that contribute to operation of the transistor and inactive regions 104 that do not contribute to operation of the transistor. The active region 102 refers to a region in which, when voltage is applied to the gate electrode 72, current flows between the source and the drain.

In the active region 102, multiple (in the example shown in FIG. 15, four) nitride semiconductor devices are continuously formed in an X-axis direction. Each nitride semiconductor device shown in FIG. 15 corresponds to the nitride semiconductor device 10 shown in FIG. 14. More specifically, the cross-sectional view shown in FIG. 14 corresponds to a cross-sectional view of the formation pattern 100 in the active region 102 enlarging a portion including one nitride semiconductor device (including gate electrode, and source electrode and drain electrode associated with the gate electrode). In the active region 102, the field plate 74B of the source electrode 74 includes the end 74C located between the drain opening 50B and the gate layer 70. The drain electrode 76 is formed in the active region 102. The drain electrode 76 is not formed in the inactive region 104. As shown in FIG. 15, the source electrode 74, the gate layer 70, and the gate electrode 72 are continuously formed over the active region 102 and the inactive region 104 in the Y-axis direction.

### Operation

The operation of the nitride semiconductor device 10 of the fifth embodiment will be described below.

The dielectric breakdown electric field of a group-III nitride semiconductor is approximately ten times greater than Si. Therefore, the group-III nitride semiconductor is a material suitable for a compact and low-resistance nitride semiconductor device. In a HEMT using the group-III nitride semiconductor, the density of the 2DEG 20 is high so that the channel resistance and the access resistance are decreased. The channel resistance is a resistance located immediately below the gate layer 70. The access resistance is the gate-source resistance and the gate-drain resistance.

In order to obtain a HEMT having a stable low resistance, the contact resistance, or a parasitic resistance, of the source electrode 74 and the drain electrode 76 with the 2DEG 20 through the electron supply layer 18 may be decreased. In this regard, in the fifth embodiment, the contact structure of the source electrode 74 with the electron supply layer 18 and the contact structure of the drain electrode 76 with the electron supply layer 18 are the same as the contact structure of the contact 32 of the electrode 30 with the electron supply layer 18 in the first embodiment. Thus, an increase in the contact resistance caused by the void VX (refer to FIG. 5) is limited. This obtains a HEMT having a stable low resistance.

In addition, the recesses 54 of the source opening 50A and the drain opening 50B in the electron supply layer 18 further decrease the contact resistances of the source electrode 74 and the drain electrode 76 with the 2DEG 20 through the electron supply layer 18. This further decreases the resistance of the HEMT.

### Advantages

The nitride semiconductor device 10 of the fifth embodiment obtains the following advantages.

(5-1) The opening 50 includes the source opening 50A and the drain opening 50B. The nitride semiconductor device 10 includes the gate electrode 72 arranged on the electron supply layer 18 and covered by the dielectric layer 22, the source electrode 74 electrically connected to the electron supply layer 18 through the source opening 50A, and the drain electrode 76 electrically connected to the electron supply layer 18 through the drain opening 50B. The electrode 30 includes at least one of the source electrode 74 or the drain electrode 76.

With this structure, the electrode 30 includes the source electrode 74. This decreases the contact resistance of the source electrode 74 with the 2DEG 20 through the electron supply layer 18. Also, the electrode 30 includes the drain electrode 76. This decreases the contact resistance of the drain electrode 76 with the 2DEG 20 through the electron supply layer 18. Thus, a HEMT having a low resistance is obtained.

(5-2) The source opening 50A, the drain opening 50B, and the gate electrode 72 are separated from each other. The source opening 50A and the drain opening 50B are located at opposite sides of the gate electrode 72. The source electrode 74 includes the field plate 74B extending from the source opening 50A to a position that is closer to the drain opening 50B than the gate electrode 72 is.

With this structure, when no gate voltage is applied to the gate electrode 72, that is, in the zero bias state, the field plate 74B reduces the concentration of an electric field in the vicinity of the end of the gate electrode 72. In addition, when a high voltage is applied to the drain electrode 76, concentration of an electric field on the one of two ends of the gate layer 70 in the X-axis direction located closer to the drain electrode 76 is reduced.

(5-3) The nitride semiconductor device 10 includes the gate layer 70 disposed on the electron supply layer 18 and composed of a semiconductor having a smaller bandgap than the electron supply layer 18. The gate electrode 72 is arranged on the gate layer 70.

With this structure, the gate layer 70 depletes the 2DEG 20 located immediately below the gate layer 70. This obtains a normally-off-type HEMT. This type of HEMT is suitable for a power device that requires a high level of safety.

(5-4) The electron supply layer 18 includes an AlₓGa₁₋ₓN layer (0.2≤x≤0.3).

With this structure, when the composition ratio of Al is 0.2 or greater and 0.3 or less, the recess 54 including the recess inclined surface 18E, the recess curved surfaces 18D, and the recess bottom surface 18C is formed in the electron supply layer 18. Accordingly, the contact resistance between the electrode 30 (the contact 32) and the 2DEG 20 through the electron supply layer 18 is less likely to increase. This obtains a HEMT having a stable low resistance.

### Modified Examples

The embodiments described above may be modified as follows. The embodiments described above and the modified examples described below can be combined as long as the combined modifications remain technically consistent with each other.

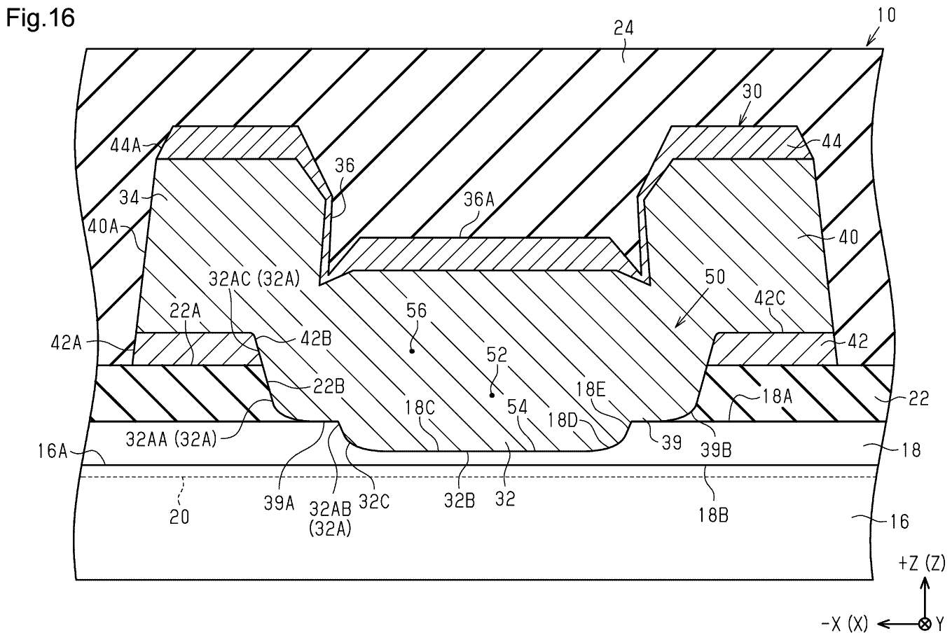

In the second embodiment, as shown in FIG. 16, the contact 32 may include a curved surface 39B disposed between the step 39 and the first part 32AA of the inclined surface 32A. In an example, the curved surface 39B and the curved surface 32C have the same structure. In an example, the arc length of the curved surface 39B is equal to the arc length of the curved surface 32C.

In the fifth embodiment, while including the source electrode 74, the electrode 30 does not necessarily have to include the drain electrode 76. More specifically, while the contact 74A of the source electrode 74 corresponds to the contact 32 of the electrode 30, the contact 76A of the drain electrode 76 does not have to correspond to the contact 32 of the electrode 30. In this case, the contact 76A does not include the inclined surface 32A and the curved surface 32C, which are included in the contact 32.

Alternatively, while including the drain electrode 76, the electrode 30 does not necessarily have to include the source electrode 74. In this case, the contact 74A of the source electrode 74 does not include the inclined surface 32A and the curved surface 32C, which are included in the contact 32 of the electrode 30.

In the fifth embodiment, the structure of at least one of the source electrode 74 or the drain electrode 76 may be changed to the electrode 30 in the second to fourth embodiments. The structure of the contact 32 of the electrode 30 corresponding to the source electrode 74 may differ from the structure of the contact 32 of the electrode 30 corresponding to the drain electrode 76.

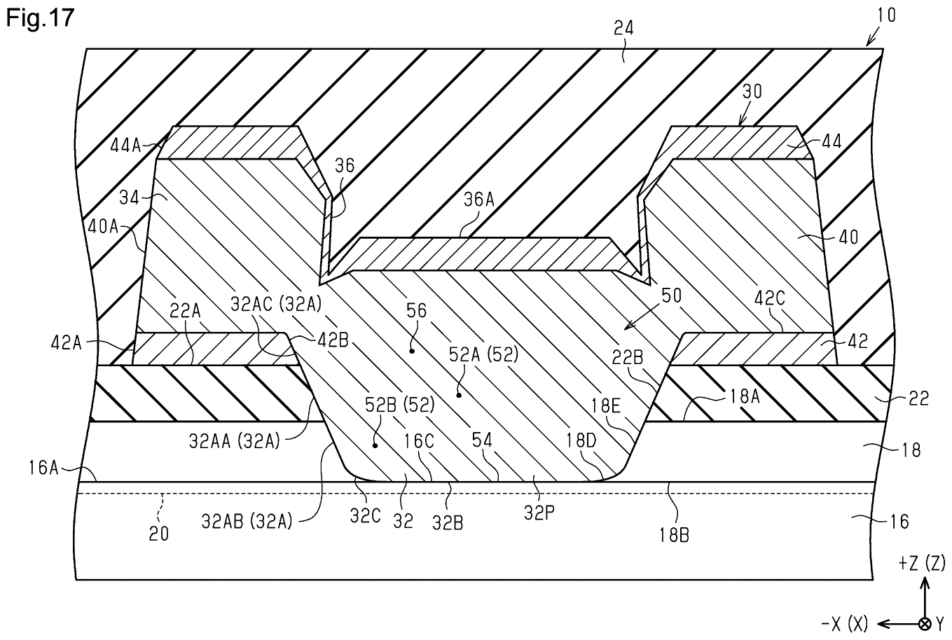

In the first and second embodiments, the position of the distal surface 32B of the contact 32 in the Z-axis direction may be changed in any manner in the range of the thickness of the electron supply layer 18. In an example, as shown in FIG. 17, the distal surface 32B of the contact 32 may be in contact with the head surface 16A of the electron transit layer 16. That is, the contact 32 may extend through the electron supply layer 18. The contact 32 is not disposed in the electron transit layer 16 in the Z-axis direction.

In the first and second embodiments, the recess inclined surface 18E may be omitted from the recess 54.

In the fourth embodiment, the recess 54 may include a recess inclined surface. The recess inclined surface is disposed in the electron transit layer 16. The recess inclined surface is inclined so that the width of the opening 50 decreases toward the recess curved surfaces 16D. The width of the opening 50 may be defined by the dimension of the opening 50 in the X-axis direction. The inclination angle of the recess inclined surface with respect to the Z-axis direction is equal to the inclination angle of the inner surface 18F of the electron supply layer 18 with respect to the Z-axis direction. The recess inclined surface is continuous and flush with the inner surface 18F.

In the fifth embodiment, the gate layer 70 may be omitted. In this case, the gate electrode 72 is formed on the electron supply layer 18. Thus, the nitride semiconductor device 10 performs a normally-on operation.

In each embodiment, the first barrier layer 42 may be omitted.

In each embodiment, the second barrier layer 44 may be omitted.

In each embodiment, the insulation layer 24 may be omitted.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. Thus, the word “on” will also allow for a structure in which another layer is arranged between the first layer and the second layer. For example, the above embodiments in which the electron supply layer 18 is formed on the electron transit layer 16 includes a structure in which an intermediate layer is disposed between the electron supply layer 18 and the electron transit layer 16 to stably form the 2DEG 20.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

The directional terms used in the present disclosure such as “vertical,” “horizontal,” “above,” “below,” “top,” “bottom,” “frontward,” “backward,” “lateral,” “left,” “right,” “front,” and “back” will depend upon a particular orientation of the device being described and illustrated. The present disclosure may include various alternative orientations. Therefore, the directional terms should not be narrowly construed.

### Clauses

Technical concepts that can be understood from each of the above embodiments and modified examples will now be described. The reference signs of the components in the embodiments are given to the corresponding components in clauses with parentheses. The reference signs are used as examples to facilitate understanding, and the components in each clause are not limited to those components given with the reference signs.

[Clause 1] A nitride semiconductor device (10), including:
an electron transit layer (16);
an electron supply layer (18) formed on the electron transit layer (16) and having a larger bandgap than the electron transit layer (16);
a dielectric layer (22) formed on the electron supply layer (18); and
an electrode (30) including a contact (32) in electrical contact with the electron supply layer (18) through an opening (50), the opening (50) extending through at least the dielectric layer (22), in which
the contact (32) includes
   an inclined surface (32A) inclined so that the contact (32) has a width that decreases toward the electron transit layer (16),
   a distal surface (32B) in contact with a surface defining a bottom of the opening (50), and
   a curved surface (32C) disposed between the distal surface (32B) and the inclined surface (32A), the curved surface (32C) being convex toward the electron transit layer (16).

[Clause 2] The nitride semiconductor device according to clause 1, in which
the opening (50) includes
   a through portion (52) extending through the dielectric layer (22), and
   a recess (54) disposed in the electron supply layer (18) and continuous with the through portion (52),
the opening (50) extends through the dielectric layer (22) and is formed in at least a portion of the electron supply layer (18),
the inclined surface (32A) includes
   a first part (32AA) in contact with the dielectric layer (22), and
   a second part (32AB) in contact with the electron supply layer (18), and the curved surface (32C) is in contact with the electron supply layer (18).

[Clause 3] The nitride semiconductor device according to clause 2, in which the distal surface (32B) is in contact with the electron supply layer (18).

[Clause 4] The nitride semiconductor device according to clause 3, in which the distal surface (32B) is located closer to the electron transit layer (16) than a center of the electron supply layer (18) in a thickness-wise direction (Z-axis direction) of the electron supply layer (18) is.

[Clause 5] The nitride semiconductor device according to clause 1, in which
the opening (50) includes
   a through portion (52) extending through the dielectric layer (22) and the electron supply layer (18), and
   a recess (54) disposed in the electron transit layer (16) and continuous with the through portion (52),
the opening (50) extends through the dielectric layer (22) and the electron supply layer (18) and is formed in at least a portion of the electron transit layer (16),
the contact (32) extends in the opening (50) through the dielectric layer (22) and the electron supply layer (18) and reaches the electron transit layer (16),
the inclined surface (32A) includes
   a first part (32AA) in contact with the dielectric layer (22), and
   a second part (32AB) in contact with the electron supply layer (18), and
the curved surface (32C) is in contact with at least the electron transit layer (16).

[Clause 6] The nitride semiconductor device according to clause 5, in which
the electron transit layer (16) includes a head surface (16A) in contact with the electron supply layer (18) and a bottom surface (16C) in contact with the distal surface (32B), and
a distance between the head surface (16A) of the electron transit layer (16) and the bottom surface (16C) of the electron transit layer (16) is less than or equal to 20 nm in a thickness-wise direction (Z-axis direction) of the electron transit layer (16).

[Clause 7] The nitride semiconductor device according to any one of clauses 2 to 6, in which
the first part (32AA) has an inclination angle with respect to a thickness-wise direction (Z-axis direction) of the electron transit layer (16), and
the second part (32AB) has an inclination angle with respect to the thickness-wise direction (Z-axis direction) of the electron transit layer (16) that is equal to the inclination angle of the first part (32AA).

[Clause 8] The nitride semiconductor device according to clause 7, in which the inclination angle of the first part (32AA) with respect to the thickness-wise direction (Z-axis direction) of the electron transit layer (16) and the inclination angle of the second part (32AB) with respect to the thickness-wise direction (Z-axis direction) of the electron transit layer (16) are each 10° or greater and 20° or less.

[Clause 9] The nitride semiconductor device according to any one of clauses 2 to 8, in which the first part (32AA) is continuous and flush with the second part (32AB).

[Clause 10] The nitride semiconductor device according to any one of clauses 2 to 8, in which
the contact (32) includes a step (39) disposed between the first part (32AA) and the second part (32AB), and
the step (39) is in contact with a head surface (18A) of the electron supply layer (18) that is in contact with the dielectric layer (22).

[Clause 11] The nitride semiconductor device according to clause 1, in which the distal surface (32B) is flush with a head surface (18A) of the electron supply layer (18) that is in contact with the dielectric layer (22).

[Clause 12] The nitride semiconductor device according to any one of clauses 1 to 11, in which
the electrode (30) includes an interconnect (34) disposed on the dielectric layer (22),
the interconnect (34) has a length (L2) in a width-wise direction (X-axis direction),
the contact (32) includes a distal portion (32P) having a length (L1) in the width-wise direction (X-axis direction), and
the length (L2) of the interconnect (34) is at least twice the length (L1) of the distal portion (32P).

[Clause 13] The nitride semiconductor device according to any one of clauses 1 to 12, in which
the electrode (30) includes an electrode layer (40), and
the electrode layer (40) includes at least Ti, Al, and Cu.

[Clause 14] The nitride semiconductor device according to clause 13, in which
the electrode (30) includes an interconnect (34) disposed on the dielectric layer (22),
the interconnect (34) includes a first barrier layer (42) in contact with the dielectric layer (22), and
the electrode layer (40) includes a portion disposed on the first barrier layer (42).

[Clause 15] The nitride semiconductor device according to clause 14, in which the first barrier layer (42) includes any of TIN, WSiN, and WN.

[Clause 16] The nitride semiconductor device according to clause 14 or 15, in which
the interconnect (34) includes a second barrier layer (44), and
the second barrier layer (44) and the first barrier layer (42) are located at opposite sides of the electrode layer (40).

[Clause 17] The nitride semiconductor device according to clause 16, in which the second barrier layer (44) includes any of TiN, WSiN, and WN.

[Clause 18] The nitride semiconductor device according to any one of clauses 1 to 17, in which the opening (50) includes a source opening (50A) and a drain opening (50B), the nitride semiconductor device, further including:
a gate electrode (72) disposed on the electron supply layer (18) and covered by the dielectric layer (22);
a source electrode (74) electrically connected to the electron supply layer (18) through the source opening (50A); and
a drain electrode (76) electrically connected to the electron supply layer (18) through the drain opening (50B),
in which the electrode (30) includes at least one of the source electrode (74) or the drain electrode (76).

[Clause 19] The nitride semiconductor device according to clause 18, in which
the source opening (50A), the drain opening (50B), and the gate electrode (72) are separated from each other,
the source opening (50A) and the drain opening (50B) are located at opposite sides of the gate electrode (72), and
the source electrode (74) includes a field plate (74B) extending from the source opening (50A) to a position that is closer to the drain opening (50B) than the gate electrode (72) is.

[Clause 20] The nitride semiconductor device according to clause 18 or 19, further including:
a gate layer (70) disposed on the electron supply layer (18) and composed of a semiconductor having a smaller bandgap than the electron supply layer (18),
in which the gate electrode (72) is disposed on the gate layer (70).

[Clause 21] The nitride semiconductor device according to any one of clauses 1 to 20, in which the electron supply layer (18) is AlₓGa₁₋ₓN layer, where 0.2≤x≤0.3.

[Clause 22] The nitride semiconductor device according to any one of clauses 13 to 17, in which the contact (32) is composed of only the electrode layer (40).

[Clause 23] The nitride semiconductor device according to clause 10, in which the contact (32) includes a curved surface (39B) disposed between the step (39) and the first part (32AA) of the inclined surface (32A).

[Clause 24] The nitride semiconductor device according to clause 1, in which
the opening (50) includes
a through portion (52) extending through the dielectric layer (22) and the electron supply layer (18), and
a recess (54) disposed in the electron supply layer (18) and continuous with the through portion (52),
the opening (50) extends through the dielectric layer (22) and the electron supply layer (18),
the contact (32) extends in the opening (50) through the dielectric layer (22) and the electron supply layer (18),
the inclined surface (32A) includes
a first part (32AA) in contact with the dielectric layer (22), and
a second part (32AB) in contact with the electron supply layer (18), and
the distal surface (32B) is in contact with a head surface (16A) of the electron transit layer (16) that is in contact with the electron supply layer (18).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer;
an electron supply layer formed on the electron transit layer and having a larger bandgap than the electron transit layer;
a dielectric layer formed on the electron supply layer; and
an electrode including a contact in electrical contact with the electron supply layer through an opening, the opening extending through at least the dielectric layer, wherein
the contact includes
an inclined surface inclined so that the contact has a width that decreases toward the electron transit layer,
a distal surface in contact with a surface defining a bottom of the opening, and
a curved surface disposed between the distal surface and the inclined surface, the curved surface being convex toward the electron transit layer.

2. The nitride semiconductor device according to claim 1, wherein
the opening includes
a through portion extending through the dielectric layer, and
a recess disposed in the electron supply layer and continuous with the through portion,
the opening extends through the dielectric layer and is formed in at least a portion of the electron supply layer,
the inclined surface includes
a first part in contact with the dielectric layer, and
a second part in contact with the electron supply layer, and
the curved surface is in contact with the electron supply layer.

3. The nitride semiconductor device according to claim 2, wherein the distal surface is in contact with the electron supply layer.

4. The nitride semiconductor device according to claim 3, wherein the distal surface is located closer to the electron transit layer than a center of the electron supply layer in a thickness-wise direction of the electron supply layer is.

5. The nitride semiconductor device according to claim 1, wherein
the opening includes
a through portion extending through the dielectric layer and the electron supply layer, and
a recess disposed in the electron transit layer and continuous with the through portion,
the opening extends through the dielectric layer and the electron supply layer and is formed in at least a portion of the electron transit layer,
the contact extends in the opening through the dielectric layer and the electron supply layer and reaches the electron transit layer,
the inclined surface includes
a first part in contact with the dielectric layer, and
a second part in contact with the electron supply layer, and
the curved surface is in contact with at least the electron transit layer.

6. The nitride semiconductor device according to claim 5, wherein
the electron transit layer includes a head surface in contact with the electron supply layer and a bottom surface in contact with the distal surface, and
a distance between the head surface of the electron transit layer and the bottom surface of the electron transit layer is less than or equal to 20 nm in a thickness-wise direction of the electron transit layer.

7. The nitride semiconductor device according to claim 2, wherein
the first part has an inclination angle with respect to a thickness-wise direction of the electron transit layer, and
the second part has an inclination angle with respect to the thickness-wise direction of the electron transit layer that is equal to the inclination angle of the first part.

8. The nitride semiconductor device according to claim 7, wherein the inclination angle of the first part with respect to the thickness-wise direction of the electron transit layer and the inclination angle of the second part with respect to the thickness-wise direction of the electron transit layer are each 10° or greater and 20° or less.

9. The nitride semiconductor device according to claim 2, wherein the first part is continuous and flush with the second part.

10. The nitride semiconductor device according to claim 2, wherein
the contact includes a step disposed between the first part and the second part, and
the step is in contact with a head surface of the electron supply layer that is in contact with the dielectric layer.

11. The nitride semiconductor device according to claim 1, wherein the distal surface is flush with a head surface of the electron supply layer that is in contact with the dielectric layer.

12. The nitride semiconductor device according to claim 1, wherein
the electrode includes an interconnect disposed on the dielectric layer,
the interconnect has a length in a width-wise direction,
the contact includes a distal portion having a length in the width-wise direction, and
the length of the interconnect is at least twice the length of the distal portion.

13. The nitride semiconductor device according to claim 1, wherein
the electrode includes an electrode layer, and
the electrode layer includes at least Ti, Al, and Cu.

14. The nitride semiconductor device according to claim 13, wherein
the electrode includes an interconnect disposed on the dielectric layer,
the interconnect includes a first barrier layer in contact with the dielectric layer, and
the electrode layer includes a portion disposed on the first barrier layer.

15. The nitride semiconductor device according to claim 14, wherein the first barrier layer includes any of TiN, WSiN, and WN.

16. The nitride semiconductor device according to claim 14, wherein
the interconnect includes a second barrier layer, and
the second barrier layer and the first barrier layer are located at opposite sides of the electrode layer.

17. The nitride semiconductor device according to claim 16, wherein the second barrier layer includes any of TiN, WSiN, and WN.

18. The nitride semiconductor device according to claim 1, wherein the opening includes a source opening and a drain opening, the nitride semiconductor device, further comprising:
a gate electrode disposed on the electron supply layer and covered by the dielectric layer;
a source electrode electrically connected to the electron supply layer through the source opening; and
a drain electrode electrically connected to the electron supply layer through the drain opening,
wherein the electrode includes at least one electrode including at least one of the source electrode or the drain electrode.

19. The nitride semiconductor device according to claim 18, wherein
the source opening, the drain opening, and the gate electrode are separated from each other,
the source opening and the drain opening are located at opposite sides of the gate electrode, and
the source electrode includes a field plate extending from the source opening to a position that is closer to the drain opening than the gate electrode is.

20. The nitride semiconductor device according to claim 18, further comprising:
a gate layer disposed on the electron supply layer and composed of a semiconductor having a smaller bandgap than the electron supply layer,
wherein the gate electrode is disposed on the gate layer.
